(19) United States
(12) Patent Application Publication
(10) Pub. No.: US 2025/0132182 A1
(43) Pub. Date: Apr. 24, 2025

(54) METHOD OF MANUFACTURING DISPLAY DEVICE

(71) Applicant: Samsung Display Co., LTD., Yongin-si (KR)

(72) Inventors: Min Gyeong SHIN, Yongin-si (KR); Dong Woo KIM, Yongin-si (KR); Won Jun LEE, Yongin-si (KR)

(73) Assignee: Samsung Display Co., LTD., Yongin-si (KR)

(21) Appl. No.: 18/760,403

(22) Filed: Jul. 1, 2024

(30) Foreign Application Priority Data
Oct. 18, 2023 (KR) 10-2023-0139279

(51) Int. Cl. H01L 21/68; H01L 33/00; H01L 33/62

(52) U.S. Cl. CPC H01L 21/68; H10H 20/01; H10H 20/857; H10H 20/0364

(57) ABSTRACT

A method of manufacturing a display device includes aligning light emitting elements in an alignment area between electrodes spaced apart from each other. The aligning of the light emitting elements includes applying a first alignment voltage to the electrodes, applying a second alignment voltage to a first signal line overlapping the alignment area, and applying a third alignment voltage to a second signal line overlapping the alignment area. The first signal line is formed of a first conductive layer, and the second signal line is formed of the first conductive layer and a second conductive layer.

### CROSS-REFERENCE TO RELATED APPLICATION(S)

This application claims priority to and benefits of Korean Patent Application No. 10-2023-0139279 under 35 U.S.C. § 119, filed on Oct. 18, 2023, in the Korean Intellectual Property Office, the entire contents of which are incorporated herein by reference.

### BACKGROUND

### 1. Technical Field

Embodiments relate to a method of manufacturing a display device.

### 2. Description of the Related Art

Recently, as interest in information displays is increased, research and development of display devices have been continuously conducted.

### SUMMARY

Embodiments provide a method of manufacturing a display device capable of improving an alignment degree of light emitting elements.

However, embodiments are not limited to those set forth herein. The above and other embodiments will become more apparent to one of ordinary skill in the art to which the disclosure pertains by referencing the detailed description of the disclosure given below.

In accordance with an aspect of the disclosure, a method of manufacturing a display device may include aligning light emitting elements in an alignment area between electrodes spaced apart from each other, wherein the aligning of the light emitting elements may include: applying a first alignment voltage to the electrodes, applying a second alignment voltage to a first signal line overlapping the alignment area, and applying a third alignment voltage to a second signal line overlapping the alignment area, and the first signal line may be formed of a first conductive layer, and the second signal line may be formed of the first conductive layer and a second conductive layer.

The first alignment voltage, the second alignment voltage, and the third alignment voltage may be simultaneously applied.

The first alignment voltage may be higher than the second alignment voltage.

The second alignment voltage may be higher than the third alignment voltage.

The electrodes may be electrically separated from the first signal line and the second signal line.

The aligning of the light emitting elements may include applying a fourth alignment voltage to a third signal line overlapping the alignment area.

The third signal line may be formed of the first conductive layer, the second conductive layer, and a third conductive layer.

The first alignment voltage, the second alignment voltage, the third alignment voltage, and the fourth alignment voltage may be simultaneously applied.

The third alignment voltage may be higher than the fourth alignment voltage.

The electrodes may be electrically separated from the third signal line.

The aligning of the light emitting elements may include applying a fifth alignment voltage to an electrode layer overlapping the alignment area.

The electrode layer may be formed of a fourth conductive layer.

The electrode layer may overlap the first signal line or the second signal line.

The first alignment voltage, the second alignment voltage, the third alignment voltage, and the fifth alignment voltage may be simultaneously applied.

The first alignment voltage may be higher than the fifth alignment voltage.

The electrodes may be electrically separated from the electrode layer.

The electrode layer may be electrically separated from the first signal line and the second signal line.

The electrode layer may overlap the electrodes.

The method may further include forming connection electrodes on the light emitting elements.

The connection electrodes may be electrically connected to the first signal line or the second signal line.

### BRIEF DESCRIPTION OF THE DRAWINGS

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawing figures, dimensions may be exaggerated for clarity of illustration. It will be understood that in case that an element is referred to as being “between” two elements, it can be the only element between the two elements, or one or more intervening elements may also be present. Like reference numerals refer to like elements throughout.

FIG. 1 is a schematic perspective view illustrating a light emitting element in accordance with an embodiment.

FIG. 2 is a schematic cross-sectional view illustrating the light emitting element in accordance with the embodiment.

FIG. 3 is a schematic plan view illustrating a display device in accordance with an embodiment.

FIG. 4 is a schematic diagram of an equivalent circuit of a pixel in accordance with an embodiment.

FIG. 5 is a schematic plan view illustrating a pixel circuit area of a pixel in accordance with an embodiment.

FIG. 6 is a schematic plan view illustrating first to third pixels in accordance with an embodiment.

FIGS. 7 and 8 are schematic plan views illustrating a pixel in accordance with an embodiment.

FIGS. 9 and 10 are schematic cross-sectional views taken along line A-A′ shown in FIG. 7.

FIGS. 11 and 12 are schematic cross-sectional views taken along line B-B′ shown in FIG. 7.

FIG. 13 is a schematic cross-sectional view taken along line C-C′ shown in FIG. 8.

FIG. 14 is a schematic cross-sectional view taken along line D-D′ shown in FIG. 8.

FIG. 15 is a schematic cross-sectional view illustrating first to third pixels in accordance with an embodiment.

FIG. 16 is a schematic cross-sectional view illustrating a pixel in accordance with an embodiment.

FIGS. 17 to 25 are schematic plan and cross-sectional views illustrating process steps of a method of manufacturing the display device in accordance with an embodiment.

FIGS. 26 to 34 are schematic plan and cross-sectional views illustrating process steps of a method of manufacturing the display device in accordance with an embodiment.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Hereinafter, embodiments will be described in more detail with reference to the accompanying drawings.

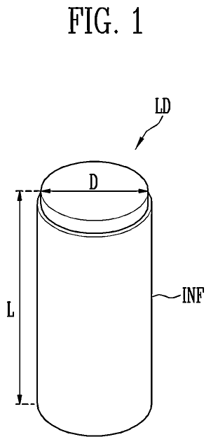

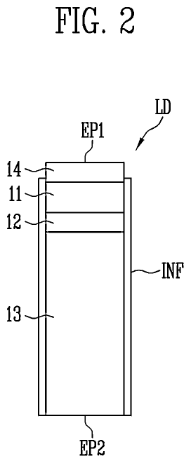

FIG. 1 is a schematic perspective view illustrating a light emitting element in accordance with an embodiment. FIG. 2 is a schematic cross-sectional view illustrating the light emitting element in accordance with the embodiment. Although a pillar-shaped light emitting element LD is illustrated in FIGS. 1 and 2, the kind and/or shape of the light emitting element LD is not limited thereto.

Referring to FIGS. 1 and 2, the light emitting element LD may include a first semiconductor layer 11, an active layer 12, a second semiconductor layer 13, and/or a contact electrode 14.

The light emitting element LD may be provided (or formed) in a pillar shape extending along one direction. The light emitting element LD may have a first end portion EP1 and a second end portion EP2. One of the first and second semiconductor layers 11 and 13 may be disposed at the first end portion EP1 of the light emitting element LD. The other of the first and second semiconductor layers 11 and 13 may be disposed at the second end portion EP2 of the light emitting element LD. For example, the first semiconductor layer 11 may be disposed at the first end portion EP1 of the light emitting element LD, and the second semiconductor layer 13 may be disposed at the second end portion EP2 of the light emitting element LD.

In some embodiments, the light emitting element LD may be a light emitting element manufactured in a pillar shape by an etching process, or the like. In the description, the term “pillar shape” may include a rod-like shape or bar-like shape, of which aspect ratio is greater than 1, such as a cylinder or a polyprism, and the shape of its section is not limited thereto.

The light emitting element LD may have a size ranging from the nanometer scale to the micrometer scale. In an example, the light emitting element LD may have a diameter D (or width) in a range of nanometer scale to micrometer scale and/or a length L in a range of nanometer scale to micrometer scale. However, the size of the light emitting element LD is not limited thereto, and the size of the light emitting element LD may be variously changed according to design conditions of various types of devices, e.g., a display device, and the like, which use, as a light source, a light emitting device using the light emitting element LD.

The first semiconductor layer 11 may be a first conductivity type semiconductor layer. For example, the first semiconductor layer 11 may include a p-type semiconductor layer. In an example, the first semiconductor layer 11 may include at least one semiconductor material among InAlGaN, GaN, AlGaN, InGaN, AlN, and InN, and include a p-type semiconductor layer doped with a first conductivity type dopant such as Mg. However, the material of the first semiconductor layer 11 is not limited thereto. For example, the first semiconductor layer 11 may be formed of various materials.

The active layer 12 may be disposed between the first semiconductor layer 11 and the second semiconductor layer 13. The active layer 12 may include any one structure among a single well structure, a multi-well structure, a single quantum well structure, a multi-quantum well (MQW) structure, a quantum dot structure, and a quantum wire structure, but embodiments are not limited thereto. The active layer 12 may include GaN, InGaN, InAlGaN, AlGaN, AlN, or the like. For example, the active layer 12 may be formed of various materials.

In case that a voltage which is a threshold voltage or more is applied to end portions (e.g., opposite end portions) of the light emitting element LD, the light emitting element LD may emit light as electron-hole pairs are combined in the active layer 12. The light emission of the light emitting element LD may be controlled by using such a principle, so that the light emitting element LD may be used as a light source for various light emitting devices, including a pixel of a display device.

The second semiconductor layer 13 may be formed on the active layer 12, and may include a semiconductor layer having a type different from the type of the first semiconductor layer 11. For example, the second semiconductor layer 13 may include an n-type semiconductor layer. In an example, the second semiconductor layer 13 may include any one semiconductor material among InAlGaN, GaN, AlGaN, InGaN, AlN, and InN, and include an n-type semiconductor layer doped with a second conductivity type dopant such as Si, Ge, or Sn. However, the material of the second semiconductor layer 13 is not limited thereto. For example, the second semiconductor layer 13 may be formed of various materials.

The contact electrode 14 may be disposed on the first end portion EP1 and/or the second end portion EP2 of the light emitting element LD. Although a case where the contact electrode 14 is formed on the first semiconductor layer 11 is an example in FIG. 2, embodiments are not limited thereto. For example, a separate contact electrode may be further disposed on the second semiconductor layer 13.

The contact electrode 14 may include a transparent metal or a transparent metal oxide. In an example, the contact electrode 14 may include at least one of indium tin oxide (ITO), indium zinc oxide (IZO), zinc oxide (ZnO), and zinc tin oxide (ZTO), but embodiments are not limited thereto. In case that the contact electrode 14 may be made of a transparent metal or a transparent metal oxide, light generated in the active layer 12 of the light emitting element LD may pass through the contact electrode 14 and be emitted to the outside of the light emitting element LD.

An insulative film INF may be provided on a surface of the light emitting element LD. The insulative film INF may be disposed (e.g., directly disposed) on surfaces of the first semiconductor layer 11, the active layer 12, the second semiconductor layer 13, and/or the contact electrode 14. The insulative film INF may expose the first and second end portions EP1 and EP2 of the light emitting element LD, which have different polarities. In some embodiments, the insulative film INF may expose a side portion(s) of the contact electrode 14 and/or the second semiconductor layer 13, adjacent to the first end portion EP1 and/or the second end portion EP2 of the light emitting element LD.

The insulative film INF may prevent an electrical short circuit which occurs in case that the active layer 12 is in contact with a conductive material except for the first and second semiconductor layers 11 and 13. The insulative film INF may minimize a surface defect of light emitting elements LD, thereby improving the lifetime and light emission efficiency of the light emitting elements LD.

The insulative film INF may include at least one of silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ). For example, the insulative film INF may be formed as a double layer, and layers included in the double layer may include different materials. In an example, the insulative film INF may be formed as a double layer including aluminum oxide (AlOₓ) and silicon oxide (SiOₓ), but embodiments are not limited thereto. In some embodiments, the insulative film INF may be omitted.

A light emitting device including the above-described light emitting element LD may be used in various kinds of devices which require a light source, including a display device. For example, light emitting elements LD may be disposed in each pixel of a display panel, and be used as a light source of each pixel. However, the application field of the light emitting element LD is not limited to the above-described example. For example, the light emitting element LD may be used in other types of devices that require a light source, such as a lighting device.

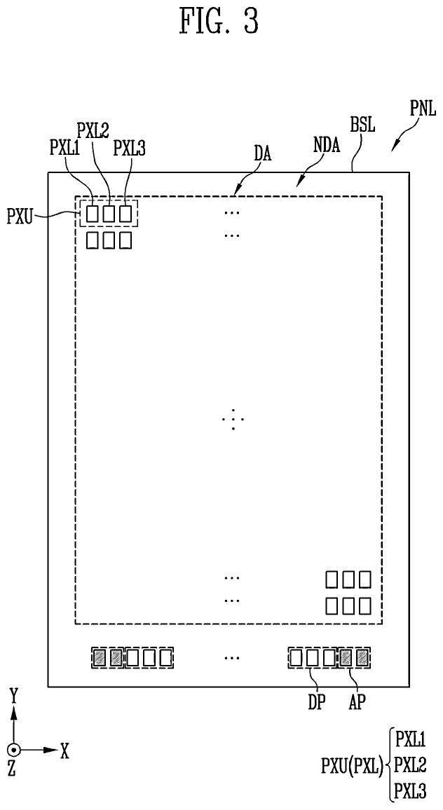

FIG. 3 is a schematic plan view illustrating a display device in accordance with an embodiment.

In FIG. 3, a display device, e.g., a display panel PNL provided (or disposed) in the display device will be illustrated as an example of an electronic device which uses, as a light source, the light emitting element LD described in the embodiment shown in FIGS. 1 and 2.

For convenience of description, in FIG. 3, a structure of the display panel PNL will be illustrated based on a display area DA. However, in some embodiments, at least one driving circuit (e.g., at least one of a scan driver and a data driver) and lines, which are not shown in the drawing, may be further disposed in the display panel PNL.

Referring to FIG. 3, the display panel PNL and a base layer BSL for forming the display panel PNL may include the display area DA for displaying an image and a non-display area NDA except for the display area DA. The display area DA may form a screen on which the image is displayed, and the non-display area NDA may be the other area except for the display area DA.

A pixel unit PXU may be disposed in the display area DA. The pixel unit PXU may include a first pixel PXL1, a second pixel PXL2, and/or a third pixel PXL3. Hereinafter, in case that at least one pixel among the first pixel PXL1, the second pixel PXL2, and the third pixel PXL3 may be arbitrarily designated or in case that two or more kinds of pixels among the first pixel PXL1, the second pixel PXL2, and the third pixel PXL3 may be inclusively designated, the corresponding pixel or the corresponding pixels will be referred to as a “pixel PXL” or “pixels PXL.”

The pixels PXL may be regularly arranged according to a stripe structure, a PENTILE™ structure, or the like. However, the arrangement structure of the pixels PXL is not limited thereto, and the pixels PXL may be arranged in the display area DA by using various structures and/or methods.

In some embodiments, two or more kinds of pixels PXL may emit lights of different colors. In an example, first pixels PXL1 emitting light of a first color, second pixels PXL2 emitting light of a second color, and third pixels PXL3 emitting light of a third color may be arranged in the display area DA. At least one first pixel PXL1, a least one second pixel PXL2, and at least one third pixel PXL3, which are disposed to be adjacent to each other, may form one pixel unit PXU capable of emitting lights of various colors. For example, each of the first to third pixels PXL1, PXL2, and PXL3 may be a pixel emitting light of a selected color. In some embodiments, the first pixel PXL1 may be a red pixel emitting light of red, the second pixel PXL2 may be a green pixel emitting light of green, and the third pixel PXL3 may be a blue pixel emitting blue light. However, embodiments are not limited thereto.

In an embodiment, the first pixel PXL1, the second pixel PXL2, and the third pixel PXL3 have light emitting elements emitting light of the same color, and may include color conversion layers and/or color filters of different colors, which are disposed on the respective light emitting elements, to respectively emit lights of the first color, the second color, and the third color. In another embodiment, the first pixel PXL1, the second pixel PXL2, and the third pixel PXL3 may respectively have, as light sources, a light emitting element of the first color, a light emitting element of the second color, and a light emitting element of the third color, so that the light emitting elements may respectively emit lights of the first color, the second color, and the third color. However, the color, kind, and/or number of pixels PXL of each pixel unit PXU are not limited thereto. In an example, the color of light emitted by each pixel PXL may be variously changed.

The pixel PXL may include at least one light source driven by a selected control signal (e.g., a scan signal and a data signal) and/or a selected power source (e.g., a first power source and a second power source). In an embodiment, the light source may include at least one light emitting element LD in accordance with the embodiment shown in FIGS. 1 and 2, e.g., a subminiature pillar-shaped light emitting element LD having a size ranging from the nanometer scale to the micrometer scale. However, embodiments are not limited thereto. For example, various types of light emitting elements LD may be used as the light source of the pixel PXL.

In an embodiment, each pixel PXL may be formed as an active pixel. However, the kind, structure, and/or driving method of pixels PXL, which are applied to the display device, are not limited thereto. For example, each pixel PXL may be formed as a pixel of a passive or active light emitting display device using various structures and/or driving methods.

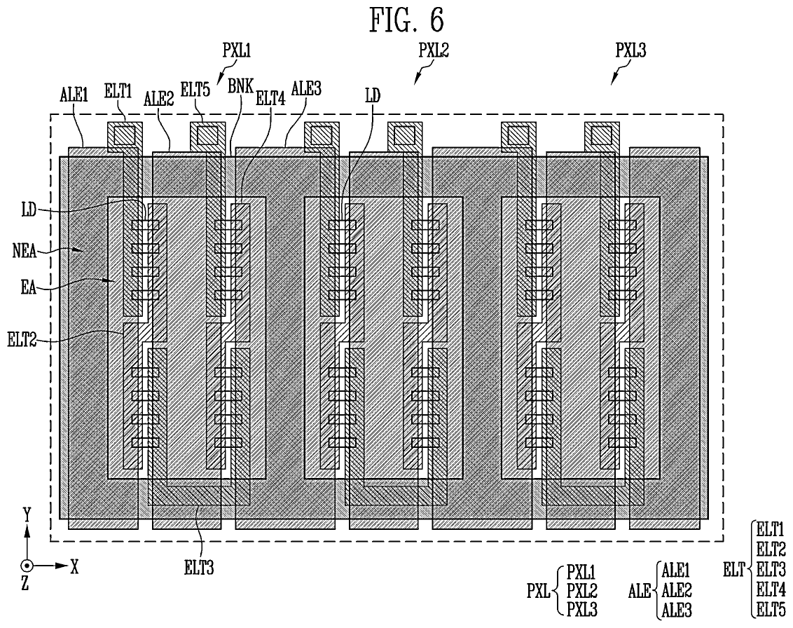

The non-display area NDA may be disposed at the periphery of the display area DA. A display pad DP and an alignment pad AP may be disposed in the non-display area NDA. The display pad DP may be electrically connected to at least one driving circuit. The pixel PXL may be electrically connected to the display pad DP through a fan-out line, to receive a driving signal from the driving circuit. Electrodes (ALE shown in FIG. 6) of the pixel PXL may be electrically connected to the alignment pad AP, to receive an alignment signal. In FIG. 3, it is illustrated that the display pad DP and the alignment pad AP are disposed at only a lower side of the display panel PNL. However, embodiments are not limited thereto. For example, the display pad DP and the alignment pad AP may be disposed at an upper side and a lower side of the display panel PNL, respectively.

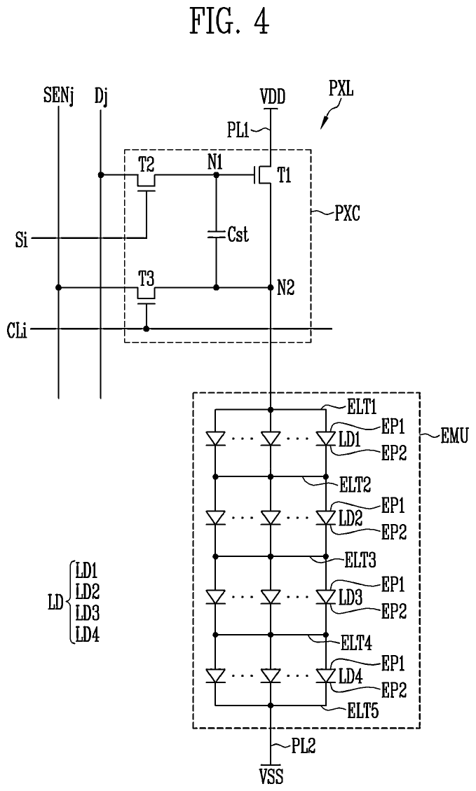

FIG. 4 is a schematic diagram of an equivalent circuit of a pixel in accordance with an embodiment.

FIG. 4 illustrates an electrical connection relationship of components included in each of the first to third pixels PXL1, PXL2, and PXL3 shown in FIG. 3, and the components included in each of the first to third pixels PXL1, PXL2, and PXL3 are not limited thereto. In FIG. 4, the pixel PXL may include not only components included in each of the first to third pixels PXL1, PXL2, and PXL3 but also an area in which the components are provided.

Referring to FIG. 4, each of the first to third pixels PXL1, PXL2, and PXL3 may include a light emitting unit EMU (or light emitting part) which generates light with a luminance corresponding to a data signal. The pixel PXL may further include a pixel circuit PXC for driving the light emitting unit EMU.

For example, the light emitting unit EMU may include a first connection electrode ELT1 connected to a first driving power source VDD through the pixel circuit PXC and a first power line PL1, a fifth connection electrode ELT5 connected to a second driving power source VSS through a second power line PL2, and light emitting elements LD connected between the first and fifth connection electrodes ELT1 and ELT5. The first driving power source VDD and the second driving power source VSS may have different potentials (or voltages) such that the light emitting elements LD may emit light. In an example, the first driving power source VDD may be set as a high-potential power source, and the second driving power source VSS may be set as a low-potential power source.

In an embodiment, the light emitting unit EMU may include at least one serial stage. Each serial stage may include a pair of electrodes (e.g., two electrodes) and at least one light emitting element LD connected in a forward-bias direction between the pair of electrodes. The number of serial stages of the light emitting unit EMU and the number of light emitting elements LD of each serial stage are not limited thereto. In an example, numbers of light emitting elements LD of the respective serial stages may be equal to or different from each other, and the number of the light emitting elements LD is not limited thereto.

For example, the light emitting unit EMU may include a first serial stage including at least one first light emitting element LD1, a second serial stage including at least one second light emitting element LD2, a third serial stage including at least one third light emitting element LD3, and a fourth serial stage including at least one fourth light emitting element LD4.

The first serial stage may include the first connection electrode ELT1, a second connection electrode ELT2, and at least one first light emitting element LD1 connected between the first and second connection electrodes ELT1 and ELT2. Each first light emitting element LD1 may be connected in the forward-bias direction between the first and second connection electrodes ELT1 and ELT2. For example, a first end portion EP1 of the first light emitting element LD1 may be connected to the first connection electrode ELT1, and a second end portion EP2 of the first light emitting element LD1 may be connected to the second connection electrode ELT2.

The second serial stage may include the second connection electrode ELT2 and a third connection electrode ELT3, and at least one second light emitting elements LD2 connected between the second and third connection electrodes ELT2 and ELT3. Each second light emitting element LD2 may be connected in the forward-bias direction between the second and third connection electrodes ELT2 and ELT3. For example, a first end portion EP1 of the second light emitting element LD2 may be connected to the second connection electrode ELT2, and a second end portion EP2 of the second light emitting element LD2 may be connected to the third connection electrode ELT3.

The third serial stage may include the third connection electrode ELT3 and a fourth connection electrode ELT4, and at least one third light emitting elements LD3 connected between the third and fourth connection electrodes ELT3 and ELT4. Each third light emitting element LD3 may be connected in the forward-bias direction between the third and fourth connection electrodes ELT3 and ELT4. For example, a first end portion EP1 of the third light emitting element LD3 may be connected to the third connection electrode ELT3, and a second end portion EP2 of the third light emitting element LD3 may be connected to the fourth connection electrode ELT4.

The fourth serial stage may include the fourth connection electrode ELT4 and the fifth connection electrode ELT5, and at least one fourth light emitting elements LD4 connected between the fourth and fifth connection electrodes ELT4 and ELT5. Each fourth light emitting element LD4 may be connected in the forward-bias direction between the fourth and fifth connection electrodes ELT4 and ELT5. For example, a first end portion EP1 of the fourth light emitting element LD4 may be connected to the fourth connection electrode ELT4, and a second end portion EP2 of the fourth light emitting element LD4 may be connected to the fifth connection electrode ELT5.

A first electrode, e.g., the first connection electrode ELT1 of the light emitting unit EMU may be an anode electrode of the light emitting unit EMU. A last electrode, e.g., the fifth connection electrode ELT5 of the light emitting unit EMU may be a cathode electrode of the light emitting unit EMU.

In case that light emitting elements LD are connected in a series/parallel structure, power efficiency may be improved as compared with the case that light emitting elements LD of which number is equal to that of the above-described light emitting elements LD are connected only in parallel. In the pixel PXL in which the light emitting elements LD are connected in the series/parallel structure, although a short defect or the like occurs in some serial stages, a luminance may be expressed (or conveyed) through light emitting elements LD of the other serial stage. Hence, the probability that a dark spot defect will occur in the pixel PXL may be reduced. However, embodiments are not limited thereto, and the light emitting unit EMU may be formed by connecting the light emitting elements LD only in series or by connecting the light emitting elements LD only in parallel.

Each of the light emitting element LD may include a first end portion EP1 (e.g., a p-type end portion) connected to the first driving power source VDD via at least one electrode (e.g., the first connection electrode ELT1), the pixel circuit PXC, and/or the first power line PL1, and a second end portion EP2 (e.g., an n-type end portion) connected to the second driving power source VSS via at least another electrode (e.g., the fifth connection electrode ELT5) and the second power line PL2. For example, the light emitting elements LD may be connected in the forward-bias direction between the first driving power source VDD and the second driving power source VSS. The light emitting elements LD connected in the forward-bias direction may form effective light sources of the light emitting unit EMU.

In case that a driving current is supplied through the corresponding pixel circuit PXC, the light emitting elements LD may emit light with a luminance corresponding to the driving current. For example, during each frame period, the pixel circuit PXC may supply, to the light emitting unit EMU, a driving current corresponding to a grayscale value to be expressed (or conveyed) in a corresponding frame. Accordingly, in case that the light emitting elements LD emit light at the luminance corresponding to the driving current, the light emitting unit EMU may express (or convey) the luminance corresponding to the driving current.

The light emitting elements LD of the light emitting unit EMU may emit light with a luminance corresponding to the driving current supplied through the corresponding pixel circuit PXC. For example, the pixel circuit PXC may supply, to the light emitting unit EMU, a driving current corresponding to a grayscale value of corresponding frame data during each frame period. The driving current supplied to the light emitting unit EMU may be divided to flow through each of the light emitting elements LD. Accordingly, the light emitting unit EMU may emit light at the luminance corresponding to the driving current in case that each light emitting element LD emits light with a luminance corresponding to the current flowing therethrough.

The pixel circuit PXC may be connected to a scan line Si and a data line Dj of the corresponding pixel PXL. In an example, the pixel PXL may be disposed on an i-th row and a j-th column of the display area DA, the pixel circuit PXC of the pixel PXL may be connected to an i-th scan line Si and a j-th data line Dj of the display area DA. The pixel circuit PXC may be connected to an i-th control line CLi and a j-th sensing line SENj of the display area DA.

The above-described pixel circuit PXC may include first to third transistors T1, T2, and T3 and a storage capacitor Cst.

The first transistor T1 may be a driving transistor for controlling a driving current applied to the light emitting unit EMU, and may be connected between the first driving power source VDD and the light emitting unit EMU. For example, a first terminal of the first transistor T1 may be connected (or coupled) to the first driving power source VDD through the first power line PL1, a second terminal of the first transistor T1 may be connected to a second node N2, and a gate electrode of the first transistor T1 may be connected to a first node N1. The first transistor T1 may control an amount of driving current applied from the first driving power source VDD to the light emitting unit EMU through the second node N2. In an embodiment, the first terminal of the first transistor T1 may be a drain electrode, and the second terminal of the first transistor T1 may be a source electrode. However, embodiments are not limited thereto. In some embodiments, the first terminal may be the source electrode, and the second terminal may be the drain electrode.

The second transistor T2 may be a switching transistor for selecting a pixel PXL in response to a scan signal and activating the pixel PXL, and may be connected between the data line Dj and the first node N1. A first terminal of the second transistor T2 may be connected to the data line Dj, a second terminal of the second transistor T2 may be connected to the first node N1, and a gate electrode of the second transistor T2 may be connected to the scan line Si. The first terminal and the second terminal of the second transistor T2 may be different terminals. For example, in case that the first terminal is a drain electrode, the second terminal may be a source electrode.

The second transistor T2 may be turned on in case that a scan signal having a gate-on voltage (e.g., a high-level voltage) is supplied from the scan line Si, to electrically connect the data line Dj and the first node N1 to each other. The first node N1 may be a point at which the second terminal of the second transistor T2 and the gate electrode of the first transistor T1 are connected to each other, and the second transistor T2 may transfer a data voltage to the gate electrode of the first transistor T1.

The third transistor T3 may connect the first transistor T1 to the sensing line SENj, to acquire (or obtain) a sensing signal through the sensing line SENj and detect a characteristic of each pixel PXL, including a threshold voltage of the first transistor T1, and the like, using the sensing signal. Information on the characteristic of each pixel PXL may be used to convert image data such that a characteristic deviation between the pixels PXL may be compensated. A second terminal of the third transistor T3 may be connected to the second terminal of the first transistor T1, a first terminal of the third transistor T3 may be connected to the sensing line SENj, and a gate electrode of the third transistor T3 may be connected to the control line CLi.

The first terminal of the third transistor T3 may be connected to an initialization power source. The third transistor T3 may be an initialization transistor capable of initializing the second node N2, and may transfer a voltage of the initialization power source to the second node N2 in case that a sensing control signal is supplied to the control line CLi. Accordingly, a second storage electrode (or upper electrode) of the storage capacitor Cst, which is connected to the second node N2, may be initialized.

A first storage electrode of the storage capacitor Cst may be connected to the first node N1, and the second storage electrode of the storage capacitor Cst may be connected to the second node N2. The storage capacitor Cst may charge a data voltage corresponding to a data signal supplied to the first node N1 during one frame period. Accordingly, the storage capacitor Cst may store a voltage corresponding to a difference between a voltage of the gate electrode of the first transistor T1 and a voltage of the second node N2.

Although an embodiment in which the first to third transistors T1, T2, and T3 are all implemented with an n-type transistor has been illustrated in FIG. 4, embodiments are not limited thereto. For example, at least one of the first, second, and third transistors T1, T2, and T3 may be changed to a p-type transistor. Although in an embodiment in which the light emitting unit EMU is connected between the pixel circuit PXC and the second driving power source VSS has been illustrated in FIG. 4, the light emitting unit EMU may be connected between the first driving power source VDD and the pixel circuit PXC.

The structure of the pixel circuit PXC may be variously modified and embodied. In an example, the pixel circuit PXC may additionally further include at least one transistor element such as a transistor element for initializing the first node N1 and/or a transistor element for controlling emission times of the light emitting elements LD, or other circuit elements such as a boosting capacitor for boosting the voltage of the first node N1.

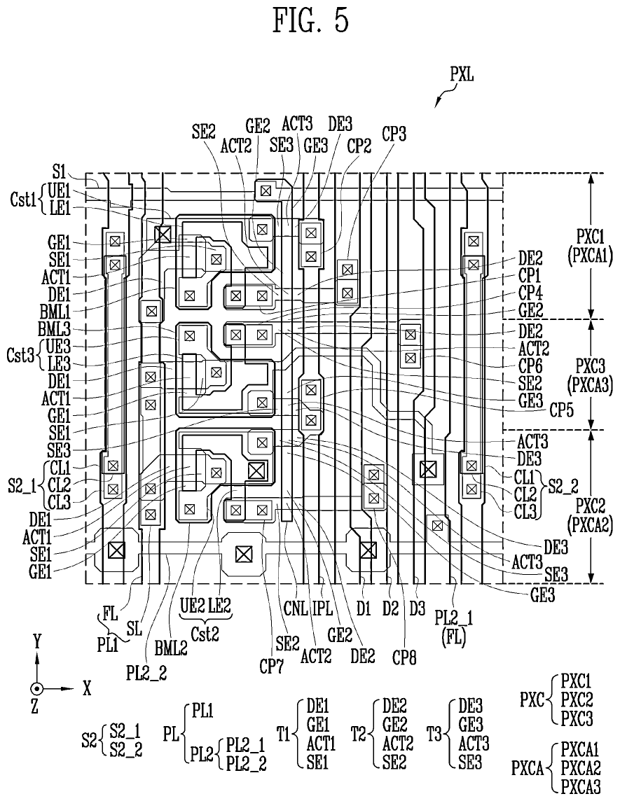

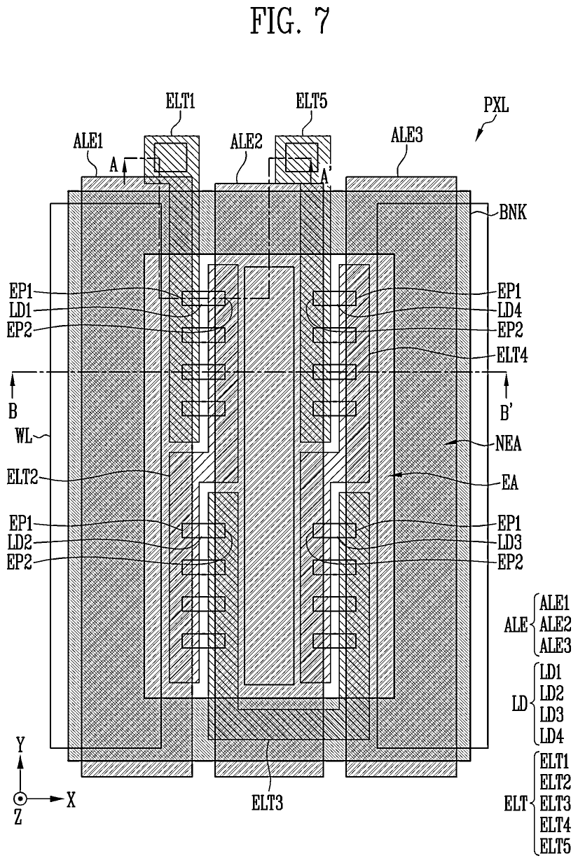

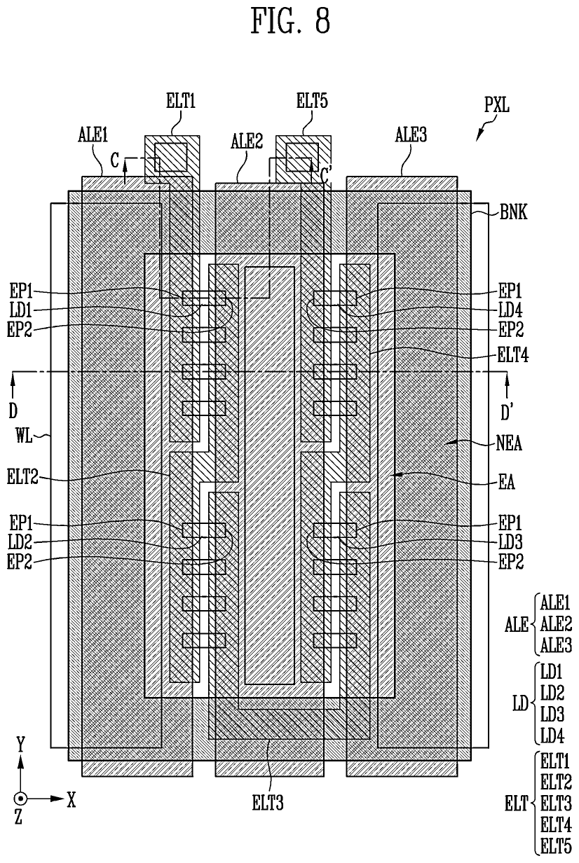

FIG. 5 is a schematic plan view illustrating a pixel circuit area PXCA of a pixel in accordance with an embodiment. FIG. 6 is a schematic plan view illustrating first to third pixels in accordance with an embodiment. In FIG. 6, for convenience of description, some components of the pixel PXL will be omitted. FIGS. 7 and 8 are schematic plan views illustrating a pixel in accordance with an embodiment. In an example, FIGS. 7 and 8 illustrate any one of first to third pixels PXL1, PXL2, and PXL3, and the first to third pixels PXL1, PXL2, and PXL3 may have structures substantially identical or similar to one another. In FIGS. 6 to 8, an embodiment in which each pixel PXL includes light emitting elements LD disposed in four serial stages as shown in FIG. 4 is illustrated. However, the number of serial stages of each pixel PXL may be variously changed in some embodiments.

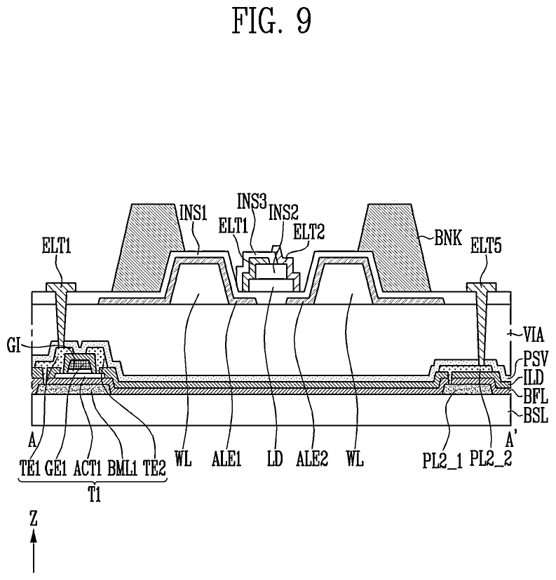

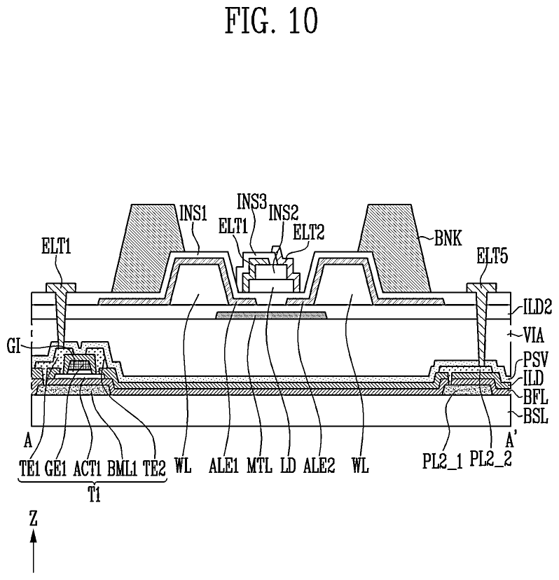

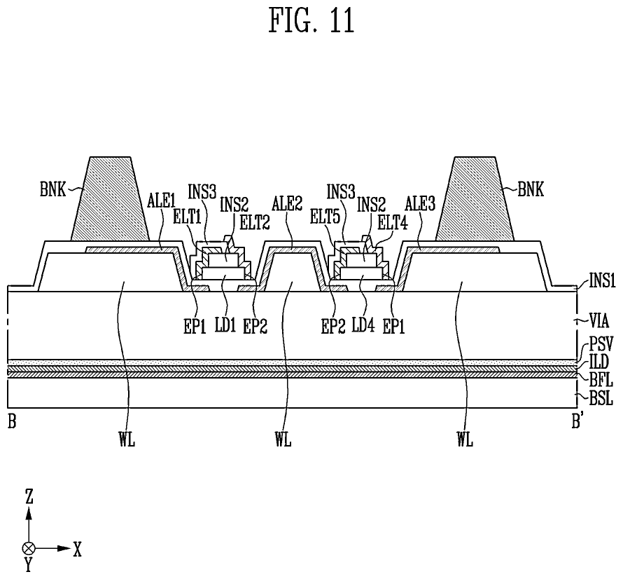

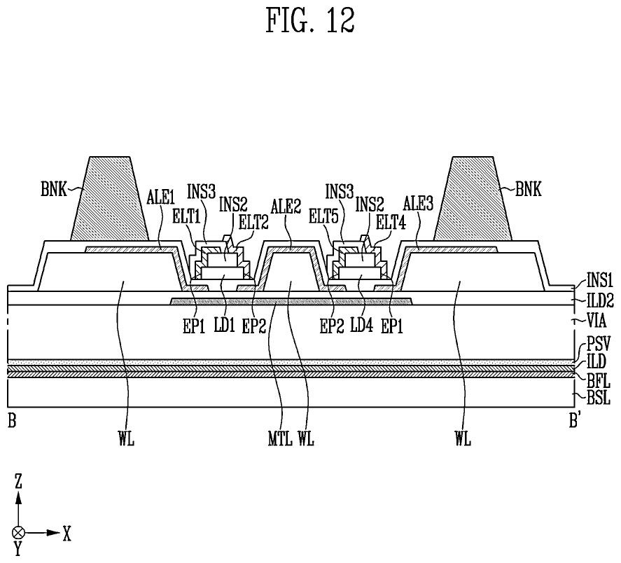

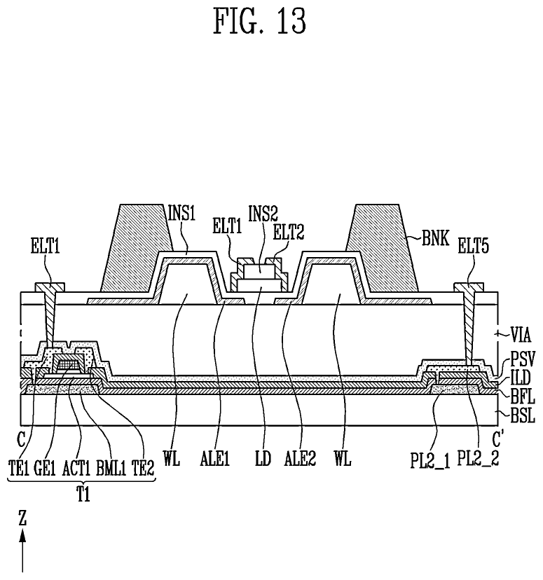

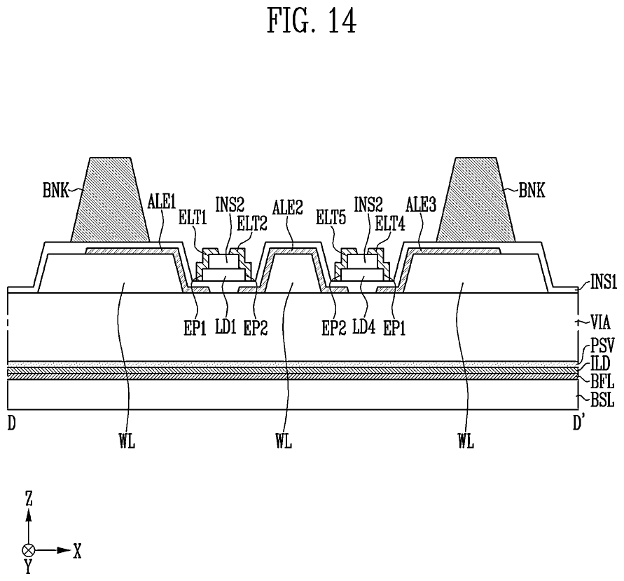

FIGS. 9 and 10 are schematic cross-sectional views taken along line A-A′ shown in FIG. 7. FIGS. 11 and 12 are schematic cross-sectional views taken along line B-B′ shown in FIG. 7. FIG. 13 is a schematic cross-sectional view taken along line C-C′ shown in FIG. 8. FIG. 14 is a schematic cross-sectional view taken along line D-D′ shown in FIG. 8.

Referring to FIG. 5, the pixel circuit PXC may include a first pixel circuit PXC1 of the first pixel PXL1, a second pixel circuit PXC2 of the second pixel PXL2, and a third pixel circuit PXC3 of the third pixel PXL3. The first pixel circuit PXC1 may be provided (or disposed) in a first pixel circuit area PXCA1, the second pixel circuit PXC2 may be provided (or disposed) in a second pixel circuit area PXCA2, and the third pixel circuit PXC3 may be provided (or disposed) in a third pixel circuit area PXCA3.

The pixel PXL may include insulating layers and conductive layers. The insulating layers may include, for example, a buffer layer BFL, a gate insulating layer GI, an interlayer insulating layer ILD, a protective layer PSV, and/or a via layer VIA, which are sequentially provided. The conductive layers may be provided and/or formed between the above-described insulating layers. The conductive layers may include a first conductive layer, a second conductive layer provided on the gate insulating layer GI, a third conductive layer provided on the interlayer insulating layer ILD, and/or a fourth conductive layer provided on the protective layer PSV. However, the insulating layers and the conductive layers are not limited to the above-described embodiment. In some embodiments, another insulating layer and another conductive layer may be further included in addition to the insulating layers and the conductive layers.

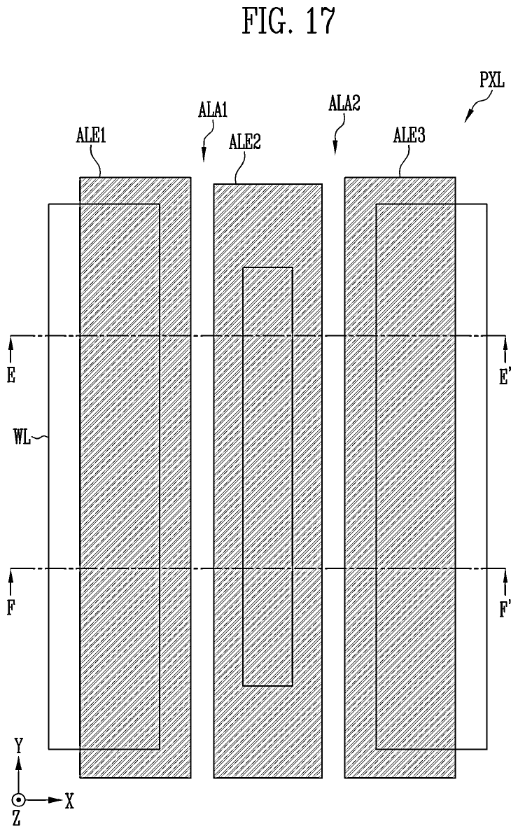

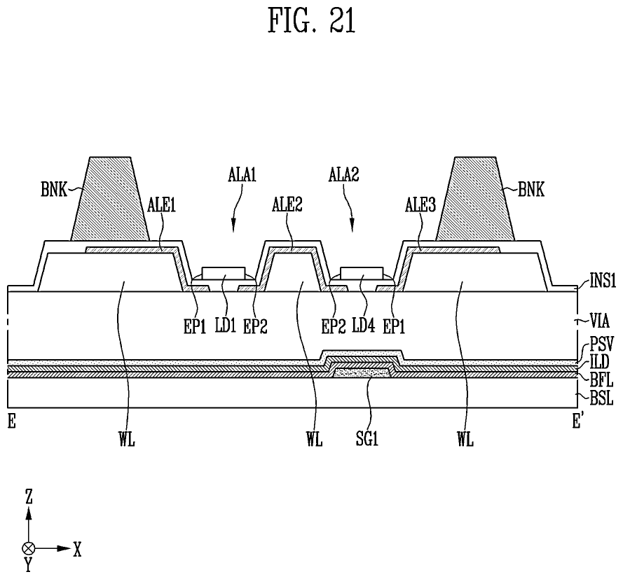

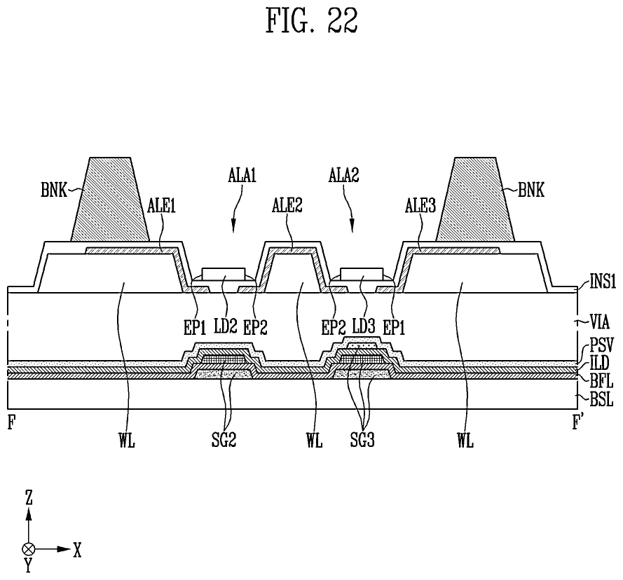

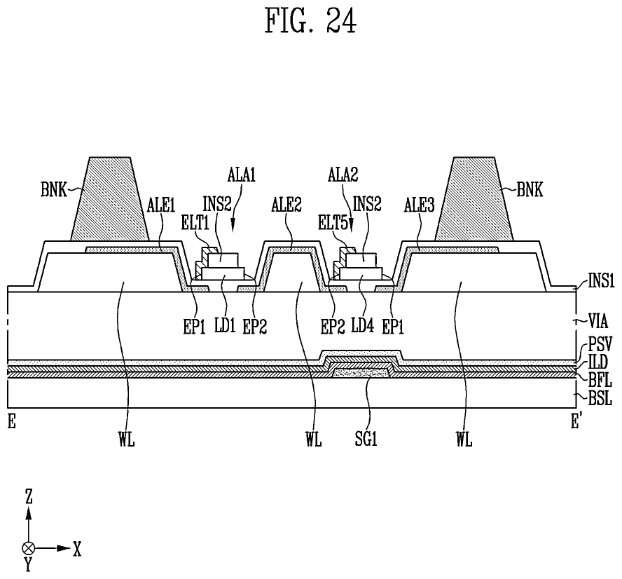

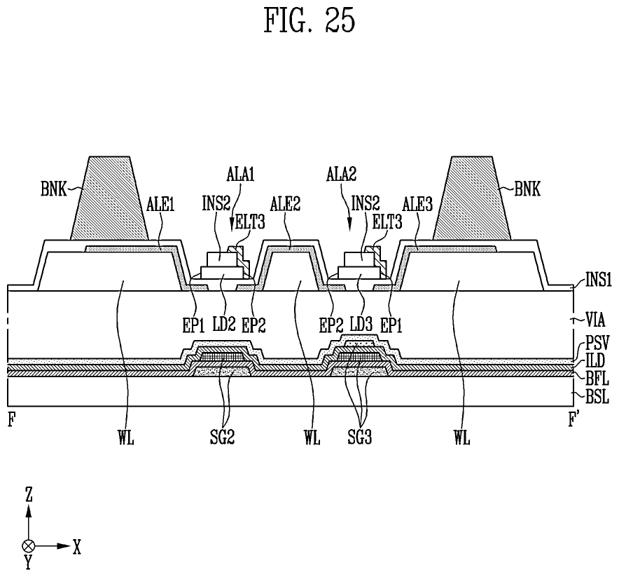

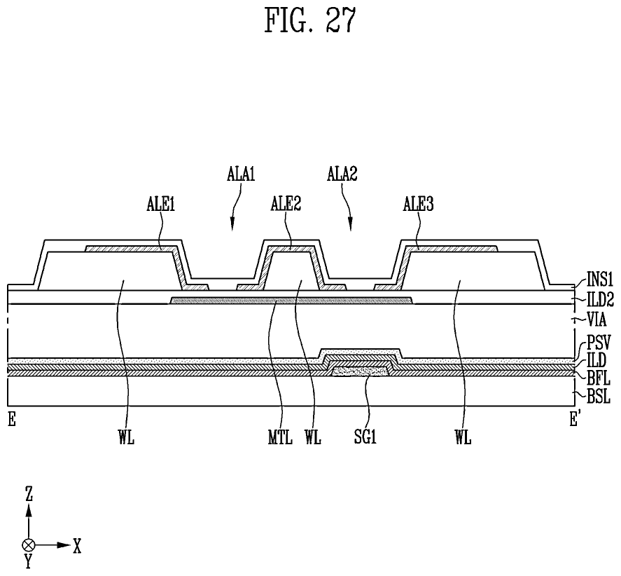

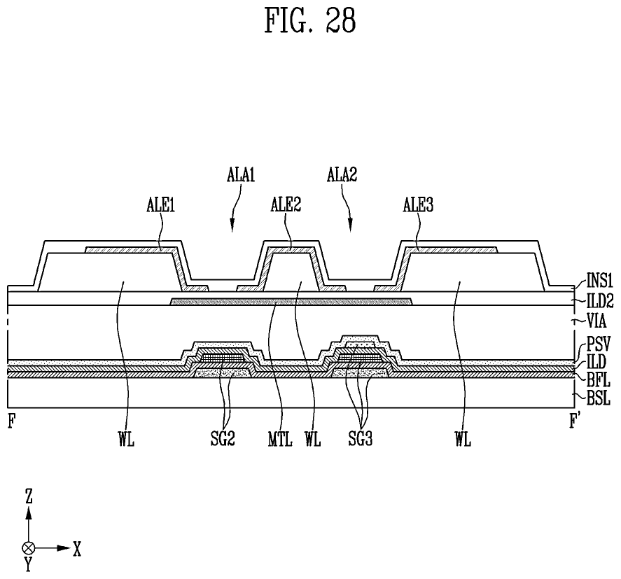

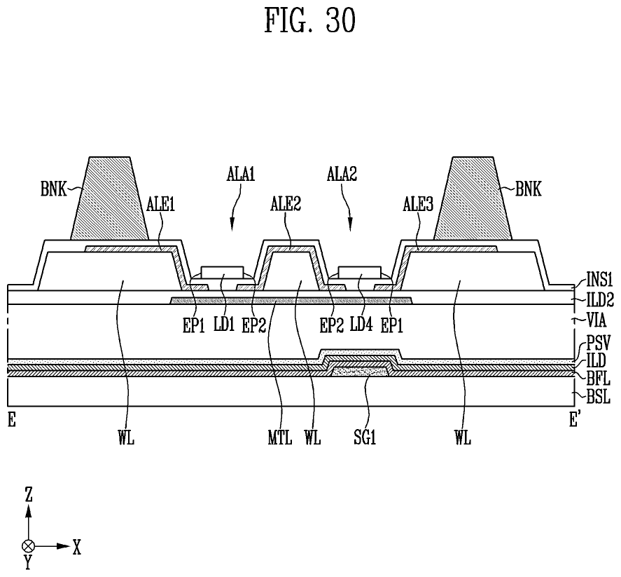

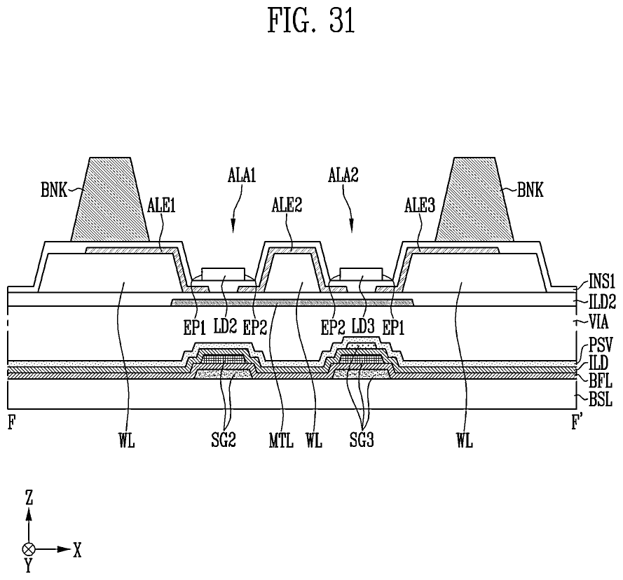

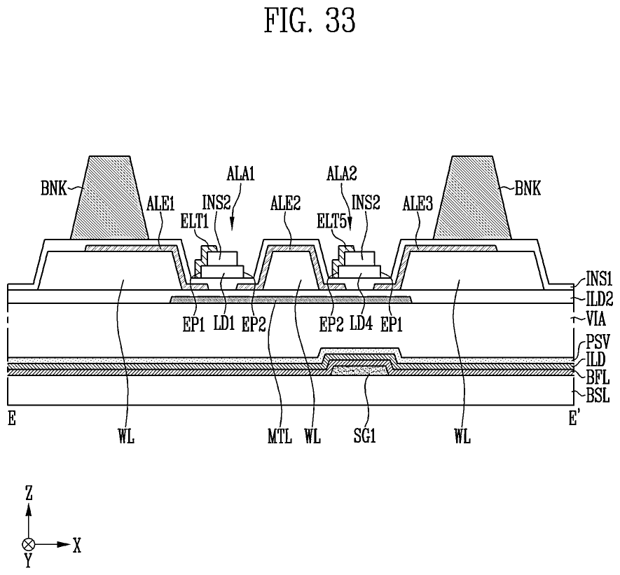

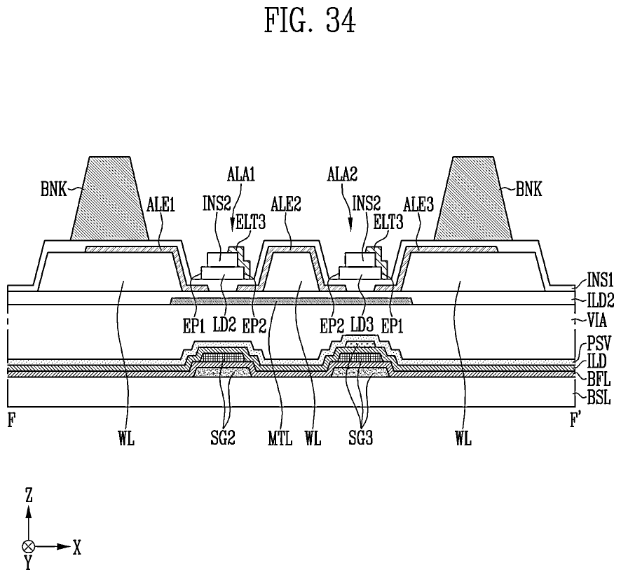

The conductive layers may include signal lines for driving a light emitting unit EMU. The signal lines may include a first scan line S1, a second scan line S2, data lines D1, D2, and D3, a power line PL, and/or an initialization power line IPL. In an embodiment, in order to improve an alignment degree of light emitting elements LD, the signal lines may supply an alignment voltage together to electrodes (ALE shown in FIG. 6) in a step of aligning the light emitting elements LD. This will be described in detail later with reference to FIGS. 17 to 34.

A scan signal and a control signal may be selectively applied to the first scan line S1. The first scan line S1 may extend along a first direction (e.g., X-axis direction). The first scan line S1 may be formed of the third conductive layer formed on the interlayer insulating layer ILD. The third conductive layer may be formed as a single layer or a multi-layer, which is made of molybdenum (Mo), copper (Cu), aluminum (Al), chromium (Cr), gold (Au), titanium (Ti), nickel (Ni), neodymium (Nd), indium (In), tin (Sn), and any oxide or ally thereof.

The first scan line S1 may be disposed on a connection line CNL, to be connected to the connection line CNL through a contact hole. In an example, the first scan line S1 may be electrically connected to the connection line CNL through a contact hole penetrating the interlayer insulating layer ILD.

The connection line CNL may be formed of the second conductive layer provided and/or formed on the gate insulating layer GI. The second conductive layer and the third conductive layer may include the same material. The second conductive layer may include at least one material selected from the materials such as the material of the third conductive layer.

In an embodiment, the connection line CNL may be integral with a second gate electrode GE2 of a second transistor T2 of each of the first to third pixel circuits PXC1, PXC2, and PXC3. In an example, a portion of the connection line CNL may be the second gate electrode GE2 of the second transistor T2 of each of the first to third pixel circuits PXC1, PXC2, and PXC3. Accordingly, the connection line CNL may be connected to the second gate electrode GE2 of the second transistor T2 of each of the first to third pixel circuits PXC1, PXC2, and PXC3.

The connection line CNL may be integral with a third gate electrode GE3 of a third transistor T3 of each of the first to third pixel circuits PXC1, PXC2, and PXC3. In an example, another portion of the connection line CNL may be the third gate electrode GE3 of the third transistor T3 of each of the first to third pixel circuits PXC1, PXC2, and PXC3. Accordingly, the connection line CNL may be connected to the third gate electrode GE3 of the third transistor T3 of each of the first to third pixel circuits PXC1, PXC2, and PXC3.

As described above, as the connection line CNL is connected to the first scan line S1 through the contact hole, the first scan line S1 may be electrically connected to some components, e.g., the second and third transistors T2 and T3 of each of the first to third pixel circuits PXC1, PXC2, and PXC3 through the connection line CNL. The first scan line S1 may supply the scan signal to the second transistor T2 of each of the first to third pixel circuits PXC1, PXC2, and PXC3 during a driving period of the light emitting elements LD, and supply the control signal to the third transistor T3 of each of the first to third pixel circuits PXC1, PXC2, and PXC3 during a sensing period.

The connection line CNL may be a common component commonly provided to the first to third pixel circuits PXC1, PXC2, and PXC3. In an example, the first to third pixel circuits PXC1, PXC2, and PXC3 may share a single connection line CNL.

The data lines D1, D2, and D3 may be spaced apart from each other along the first direction (e.g., X-axis direction), and include a first data line D1, a second data line D2, and a third data line D3, which extend in a second direction (e.g., Y-axis direction) intersecting the first direction (e.g., X-axis direction). A data signal may be applied to each of the first to third data lines D1, D2, and D3. Each of the first to third data lines D1, D2, and D3 may be the j-th data line described with reference to FIG. 4.

The first data line D1 may be electrically connected to a second transistor T2 of the first pixel circuit PXC1, the second data line D2 may be electrically connected to a second transistor T2 of the second pixel circuit PXC2, and the third data line D3 may be electrically connected to a second transistor T2 of the third pixel circuit PXC3. The first to third data lines D1, D2, and D3 may be formed of the first conductive layer provided on a base layer BSL. The first conductive layer and the third conductive layer may include the same material. The first conductive layer may include at least one material selected from the materials such as the material of the third conductive layer.

The power line PL may include a first power line PL1 and a second power line PL2. The voltage of the first driving power source (VDD shown in FIG. 4) may be applied to the first power line PL1. The first power line PL1 may extend along the second direction (e.g., Y-axis direction). In an embodiment, the first power line PL1 may include a first layer FL and a second layer SL. The first layer FL may be formed of the first conductive layer provided and/or formed on the base layer BSL. The second layer SL may be formed of the third conductive layer provided and/or formed on the interlayer insulating layer ILD. The first layer FL and the first to third data lines D1, D2, and D3 may be provided/disposed in (or formed as) the same layer (e.g., first conductive layer). The second layer SL and the first scan line S1 may be provided or disposed in (or formed as) the same layer (e.g., third conductive layer). The second layer SL may be electrically connected to the first layer FL through at least one contact hole. In an example, the second layer SL may be electrically connected to the first layer FL through at least one contact hole sequentially penetrating the buffer layer BFL, the gate insulating layer GI, and the interlayer insulating layer ILD.

The voltage of the second driving power source (VSS shown in FIG. 4) may be applied to the second power line PL2. The second power line PL2 may include a vertical power line PL2_1 and a horizontal power line PL2_2.

The vertical power line PL2_1 may extend in the second direction (e.g., Y-axis direction). The vertical power line PL2_1 may be implemented in a single-layer structure including the first layer FL. The first layer FL may be formed of the first conductive layer provided and/or formed on the base layer BSL. The first layer FL of the first power line PL1 and the first to third data lines D1, D2, and D3 may be provided/disposed in (or formed as) the same layer (e.g., first conductive layer). The first layer FL may be spaced apart from the first to third data lines D1, D2, and D3 and the first power line PL1 in plan view.

The vertical power line PL2_1 and the horizontal power line PL2_2 may be electrically connected to each other through a contact hole. In an example, the horizontal power line PL2_2 may be electrically connected to the vertical power line PL2_1 through a contact hole sequentially penetrating the buffer layer BFL, the gate insulating layer GI, and the interlayer insulating layer ILD. The second power line PL2 including the vertical power line PL2_1 and the horizontal power line PL2_2 may have a mesh structure.

The second scan line S2 may extend in the second direction (e.g., Y-axis direction) intersecting the first direction (e.g., X-axis direction) as the extension direction of the first scan line S1. The second scan line S2 may at least partially overlap the first scan line S1 with intersecting the first scan line S1. The second scan line S2 may supply the scan signal during the driving period of the light emitting elements LD, and may supply the control signal during the sensing period.

In an embodiment, the second scan line S2 may include a (2-1)th scan line S2_1 and a (2-2)th scan line S2_2. Each of the (2-1)th scan line S2_1 and the (2-2)th scan line S2_2 may be disposed to be adjacent to the power line PL, and be spaced apart from the power line PL. In an example, the (2-1)th scan line S2_1 may be disposed to be adjacent to the first power line PL1 extending in the second direction (e.g., Y-axis direction), and be spaced apart from the first power line PL1. The (2-2)th scan line S2_2 may be disposed to be adjacent to the vertical power line PL2_1 extending in the second direction (e.g., Y-axis direction), and be spaced apart from the vertical power line PL2_1.

In an embodiment, each of the (2-1)th scan line S2_1 and the (2-2)th scan line S2_2 may be implemented in a triple-layer structure including a first conductive line CL1, a second conductive line CL2, and a third conductive line CL3. The first conductive line CL1 may be formed of the first conductive layer provided and/or formed on the base layer BSL, the second conductive line CL2 may be formed of the second conductive layer provided and/or formed on the gate insulating layer GI, and the third conductive line CL3 may be formed of the third conductive layer provided and/or formed on the interlayer insulating layer ILD.

The first conductive line CL1, the first to third data lines D1, D2, and D3, the first layer FL of the first power line PL1, and the vertical power line PL2_1 of the second power line PL2 may be provided/disposed in (or formed as) the same layer (e.g., first conductive layer). The second conductive line CL2 and the connection line CNL may be provided/disposed (or formed as) in the same layer (e.g., second conductive layer). The third conductive line CL3 and the first scan line S1 and the second layer SL of the first power line PL1 may be provided/disposed in (or formed as) the same layer (e.g., third conductive layer). The third conductive line CL3 may be connected to each of the first conductive line CL1 and the second conductive line CL2 through a contact hole. In an example, the third conductive line CL3 may be electrically connected to the first conductive line CL1 through a contact hole sequentially penetrating the buffer layer BFL, the gate insulating layer GI, and the interlayer insulating layer ILD. The third conductive line CL3 may be electrically connected to the second conductive line CL2 through a contact hole penetrating the interlayer insulating layer ILD. Accordingly, the first conductive line CL1 and the second conductive line CL2 may be connected to each other through the third conductive line CL3.

In an embodiment, the third conductive line CL3 may be provided and/or formed on the second conductive line CL2 with the interlayer insulating layer ILD interposed between the second conductive line CL2 and the third conductive line CL3. The second conductive line CL2 may be provided and/or formed on the first conductive line CL1 with the gate insulating layer GI and the buffer layer BFL, which are interposed between the first conductive line CL1 and the second conductive line CL2. The first conductive line CL1, the second conductive line CL2, and the third conductive line CL3 may overlap each other in plan view and a section.

In an embodiment, it has been described that the (2-1)th scan line S2_1 and the (2-2)th scan line S2_2 are implemented in the triple-layer structure including the first conductive line CL1, the second conductive line CL2, and the third conductive line CL3. However, embodiments are not limited thereto. In some embodiments, the (2-1)th scan line S2_1 and the (2-2)th scan line S2_2 may be implemented in a single-layer structure, a double-layer structure, or a multi-layer structure including three or more layers.

The initialization power line IPL may extend in the second direction (e.g., Y-axis direction), and be disposed between the first power line PL1 and the first data line D1. The initialization power line IPL may be the j-th sensing line SENj described with reference to FIG. 4. The voltage of the initialization power source may be applied to the initialization power line IPL. In an embodiment, the initialization power line IPL may be formed of the first conductive layer provided and/or formed on the base layer BSL. The initialization power line IPL, the first to third data lines D1, D2, and D3, the first layer FL of the first power line PL1, the vertical power line PL2_1 of the second power line PL2, and the first conductive line CL1 of the second scan line S2 may be provided/disposed in (or formed as) the same layer (e.g., first conductive layer).

The initialization power line IPL may be electrically connected to the third transistor T3 of the first pixel circuit PXC1 through a second conductive pattern CP2, and be electrically connected to a third transistor T3 of each of the second and third pixel circuits PXC2 and PXC3 through a fifth conductive pattern CP5.

The second conductive pattern CP2 may be formed of the third conductive layer provided and/or formed on the interlayer insulating layer ILD. The second conductive pattern CP2 and the first scan line S1 may be provided/disposed in (or formed as) the same layer (e.g., third conductive layer).

An end portion of the second conductive pattern CP2 may be connected to the initialization power line IPL through a contact hole. In an example, the end portion of the second conductive pattern CP2 may be electrically connected to the initialization power line IPL through a contact hole sequentially penetrating the buffer layer BFL, the gate insulating layer GI, and the interlayer insulating layer ILD.

The other end portion of the second conductive pattern CP2 may be connected to the third transistor T3 of the first pixel circuit PXC1 through a contact hole. In an example, the other end portion of the second conductive pattern CP2 may be electrically connected to a third drain region of the third transistor T3 of the first pixel circuit PXC1 through a contact hole sequentially penetrating the gate insulating layer GI and the interlayer insulating layer ILD.

The fifth conductive pattern CP5 may be formed of the third conductive layer provided and/or formed on the interlayer insulating layer ILD. The fifth conductive pattern CP5 and the second conductive pattern CP2 may be provided/disposed in (or formed as) the same layer (e.g., third conductive layer).

An end portion of the fifth conductive pattern CP5 may be connected to the initialization power line IPL through a contact hole. In an example, the end portion of the fifth conductive pattern CP5 may be electrically connected to the initialization power line IPL through a contact hole sequentially penetrating the buffer layer BFL, the gate insulating layer GI, and the interlayer insulating layer ILD.

The other end portion of the fifth conductive pattern CP5 may be connected to the third transistor T3 of each of the second and third pixel circuits PXC2 and PXC3 through a contact hole. In an example, the other end portion of the fifth conductive pattern CP5 may be electrically connected to a third drain region DE3 of the third transistor T3 of each of the second and third pixel circuits PXC2 and PXC3 through a contact hole sequentially penetrating the gate insulating layer GI and the interlayer insulating layer ILD.

The first power line PL1, the second power line PL2, the initialization power line IPL, the connection line CNL, the first scan line S1, and the second scan line S2, which are described above, may be common components commonly provided (or disposed) in the first to third pixel circuits PXC1, PXC2, and PXC3.

Each of the first to third pixel circuits PXC1, PXC2, and PXC3 may include a first transistor T1, a second transistor T2, a third transistor T3, and a storage capacitor Cst. In an example, the first pixel circuit PXC1 may include first to third transistors T1, T2, and T3, and a first storage capacitor Cst1. The second pixel circuit PXC2 may include first to third transistors T1, T2, and T3 and a second storage capacitor Cst2. The third pixel circuit PXC3 may include first to third transistors T1, T2, and T3 and a third storage capacitor Cst3.

The first pixel circuit PXC1, the second pixel circuit PXC2, and the third pixel circuit PXC3 may have structures substantially similar or identical to one another. Hereinafter, the first pixel circuit PXC1 among the first to third pixel circuits PXC1, PXC2, and PXC3 will be mainly described, and the second and third pixel circuits PXC2 and PXC3 will be described.

The first pixel circuit PXC1 may include the first transistor T1, the second transistor T2, the third transistor T3, and the first storage capacitor Cst1.

The first transistor T1 may include a first gate electrode GE1, a first active pattern ACT1, a first source region SE1, and a first drain region DE1.

The first gate electrode GE1 may be connected to a second source region SE2 of the second transistor T2 through a first conductive pattern CP1. The first gate electrode GE1 may be formed of the second conductive layer provided and/or formed on the gate insulating layer GI. The first gate electrode GE1 and the connection line CNL may be provided/disposed in (or formed as) the same layer (e.g., second conductive layer).

The first conductive pattern CP1 may be formed of the third conductive layer. An end portion of the first conductive pattern CP1 may be connected to the first gate electrode GE1 through a contact hole. In an example, the end portion of the first conductive pattern CP1 may be electrically connected to the first gate electrode GE1 through a contact hole penetrating the interlayer insulating layer ILD. The other end portion of the first conductive pattern CP1 may be connected to the second source region SE2 through a contact hole. In an example, the other end portion of the first conductive pattern CP1 may be electrically connected to the second source region SE2 through a contact hole sequentially penetrating the gate insulating layer GI and the interlayer insulating layer ILD.

Each of the first active pattern ACT1, the first source region SE1, and the first drain region DE1 may be a semiconductor pattern made of poly-silicon, amorphous silicon, an oxide semiconductor, or the like. Each of the first active pattern ACT1, the first source region SE1, and the first drain region DE1 may be formed of a semiconductor layer undoped or doped with an impurity. In an example, each of the first source region SE1 and the first drain region DE1 may be formed of a semiconductor layer doped with the impurity, and the first active pattern ACT1 may be formed of a semiconductor layer undoped with the impurity. In an example, an n-type impurity may be used as the impurity.

The first active pattern ACT1, the first source region SE1, and the first drain region DE1 may be provided and/or formed on the buffer layer BFL.

The first active pattern ACT1 may be a region overlapping the first gate electrode GE1, and may be a channel region of the first transistor T1. In case that the first active pattern ACT1 is formed long, the channel region of the first transistor T1 may be formed long. The driving range of a voltage applied to the first transistor T1 may be widened. Accordingly, the grayscale of light (or lay) emitted from the light emitting elements LD may be minutely controlled.

The first source region SE1 may be connected to (or in contact with) an end portion of the first active pattern ACT1. The first source region SE1 may be electrically connected to a first lower conductive layer BML1 through a contact hole penetrating the buffer layer BFL.

The first lower conductive layer BML1 may be formed of the first conductive layer provided and/or formed on the base layer BSL. The first lower conductive layer BML1, the first to third data lines D1, D2, and D3, the first power line PL1, the vertical power line PL2_1, the first conductive line of the second scan line S2, and the initialization power line IPL may be provided/disposed in (or formed as) the same layer (e.g., first conductive layer). The first lower conductive layer BML1 may be electrically connected to the first source region SE1 through a contact hole. In case that the first lower conductive layer BML1 is connected to the first transistor T1, a swing width margin of the second driving power source VSS may be further ensured. The driving range of a voltage supplied to the first gate electrode GE of the first transistor T1 may be widened.

The first drain region DE1 may be connected to (or in contact with) the other end portion of the first active pattern ACT1. The first drain region DE1 may be connected to the first power line PL1 through a contact hole. In an example, the first drain region DE1 may be electrically connected to the first layer FL of the first power line PL1 through a contact hole penetrating the buffer layer BFL.

The second transistor T2 may include a second gate electrode GE2, a second active pattern ACT2, the second source region SE2, and a second drain region DE2.

The second gate electrode GE2 may be integral with the connection line CNL. The second gate electrode GE2 may be a region of the connection line CNL. As described above, since the connection line CNL is connected to the first scan line S1 through a contact hole, a signal (e.g., the scan signal) applied to the first scan line S1 may be finally supplied to the second gate electrode GE2.

Each of the second active pattern ACT2, the second source region SE2, and the second drain region DE2 may be a semiconductor pattern made of poly-silicon, amorphous silicon, an oxide semiconductor, or the like. Each of the second active pattern ACT2, the second source region SE2, and the second drain region DE2 may be formed of a semiconductor layer undoped or doped with an impurity. In an example, each of the second source region SE2 and the second drain region DE2 may be formed of a semiconductor layer doped with the impurity, and the second active pattern ACT2 may be formed of a semiconductor layer undoped with the impurity. In an example, an n-type impurity may be used as the impurity.

The second active pattern ACT2, the second source region SE2, and the second drain region DE2 may be provided and/or formed on the buffer layer BFL.

The second active pattern ACT2 may be a region overlapping the second gate electrode GE2, and may be a channel region of the second transistor T2.

The second source region SE2 may be connected to (or in contact with) an end portion of the second active pattern ACT2. The second source region SE2 may be connected to the first gate electrode GE1 through the first conductive pattern CP1.

The second drain region DE2 may be connected to (or in contact with) the other end portion of the second active pattern ACT2. The second drain region DE2 may be connected to the first data line D1 through a third conductive pattern CP3.

The third conductive pattern CP3 may be formed of the third conductive layer provided and/or formed on the interlayer insulating layer ILD. An end portion of the third conductive pattern CP3 may be electrically connected to the first data line D1 through a contact hole sequentially penetrating the buffer layer BFL, the gate insulating layer GI, and the interlayer insulating layer ILD. The other end portion of the third conductive pattern CP3 may be connected to the second drain region DE2 through a contact hole sequentially penetrating the gate insulating layer GI and the interlayer insulating layer ILD. The second drain region DE2 and the first data line D1 may be electrically connected to each other through the third conductive pattern CP3.

The third transistor T3 may include a third gate electrode GE3, a third active pattern ACT3, a third source region SE3, and a third drain region DE3.

The third gate electrode GE3 may be integral with the connection line CNL. The third gate electrode GE3 may be another region of the connection line CNL. As described above, since the connection line CNL is connected to the first scan line S1 through a contact hole, a signal (e.g., the control signal) applied to the first scan line S1 may be finally supplied to the third gate electrode GE3.

Each of the third active pattern ACT3, the third source region SE3, and the third drain region DE3 may be a semiconductor pattern made of poly-silicon, amorphous silicon, an oxide semiconductor, or the like. Each of the third active pattern ACT3, the third source region SE3, and a third drain region DE3 may be formed of a semiconductor layer undoped or doped with an impurity. In an example, each of the third source region SE3 and the third drain region DE3 may be formed of a semiconductor layer doped with the impurity, and the third active pattern ACT3 may be formed of a semiconductor layer undoped with the impurity. In an example, an n-type impurity may be used as the impurity.

The third active pattern ACT3, the third source region SE3, and the third drain region DE3 may be provided and/or formed on the buffer layer BFL.

The third active pattern ACT3 may be a region overlapping the third gate electrode GE3, and may be a channel region of the third transistor T3.

The third source region SE3 may be connected to (or in contact with) an end portion of the third active pattern ACT3. The third source region SE3 may be electrically connected to the first lower conductive layer BML1 through a contact hole penetrating the buffer layer BFL.

The third drain region DE3 may be connected to (or in contact with) the other end portion of the third active pattern ACT3. The third drain region DE3 may be electrically connected to the initialization power line IPL through the second conductive pattern CP2.

The first storage capacitor Cst1 may include a first lower electrode LE1 and a first upper electrode UE1. The first storage capacitor Cst1 may be the storage capacitor Cst described with reference to FIG. 4.

The first lower electrode LE1 may be integral with the first gate electrode GE1. In an example, the first lower electrode LE1 may be a region of the first gate electrode GE1.

The first upper electrode UE1 may be disposed on the first lower electrode LE1 with overlapping the first lower electrode LE1 in plan view, and have a size (or area) greater than a size (or area) of the first lower electrode LE1. However, embodiments are not limited thereto.

The first upper electrode UE1 may overlap each of the first source region SE1 and the third source region SE3 in plan view. The first upper electrode UE1 may be formed of the third conductive layer provided and/or formed on the interlayer insulating layer ILD3.

The first upper electrode UE1 may be electrically connected to the first lower conductive layer BML1 through a contact hole sequentially penetrating the buffer layer BFL, the gate insulating layer GI, and the interlayer insulating layer ILD. As described above, since the first source region SE and the third source region SE3 are electrically connected to the first lower conductive layer BML1, the first upper electrode UE1 may be electrically connected to the first and third source regions SE1 and SE3 through the first lower conductive layer BML1.

The second pixel circuit PXC2 may include the first transistor T1, the second transistor T2, the third transistor T3, and the second storage capacitor Cst2.

The first transistor T1 may include a first gate electrode GE1, a first active pattern ACT1, a first source region SE1, and a first drain region DE1.

The first gate electrode GE1 may be connected to a second source region SE2 of the second transistor T2.

The first active pattern ACT1 may be a channel region of the first transistor T1.

The first source region SE1 may be connected to the first active pattern ACT1. The first source region SE1 may be electrically connected to a second lower conductive layer BML2 through a contact hole penetrating the buffer layer BFL.

The second lower conductive layer BML2 may be a component corresponding to the first lower conductive layer BML1. The second lower conductive layer BML2 may be formed of the first conductive layer provided and/or formed on the base layer BSL. The second lower conductive layer BML2 may be electrically connected to the first source region SE1 through a contact hole. The second lower conductive layer BML2 may be electrically connected to a third source region SE3 of the third transistor T3 through a contact hole penetrating the buffer layer BFL. The second lower conductive layer BML2 may be electrically connected to a second upper electrode UE2 of the second storage capacitor Cst2 through a contact hole sequentially penetrating the buffer layer BFL, the gate insulating layer GI, and the interlayer insulating layer ILD.

The first drain region DE1 may be connected to the first active pattern ACT1. The first drain region DE1 may be electrically connected to the first layer FL of the first power line PL1 through a contact hole penetrating the buffer layer BFL.

The second transistor T2 may include a gate electrode GE2, a second active pattern ACT2, the second source region SE2, and a second drain region DE2.

The second gate electrode GE2 may be integral with the connection line CNL, and be connected to the first scan line S1.

The second active pattern ACT2 may be a channel region of the second transistor T2.

The second source region SE2 may be connected to the second active pattern ACT2. The second source region SE2 may be connected to the first gate electrode GE1 through a seventh conductive pattern CP7.

The seventh conductive pattern CP7 may be formed of the third conductive layer provided and/or formed on the interlayer insulating layer ILD. An end portion of the seventh conductive pattern CP7 may be electrically connected to the second source region SE2 through a contact hole sequentially penetrating the gate insulating layer GI and the interlayer insulating layer ILD. The other end portion of the seventh conductive pattern CP7 may be connected to the first gate electrode GE1 through a contact hole penetrating the interlayer insulating layer ILD.

The second drain region DE2 may be connected to the second active pattern ACT2. The second drain region DE2 may be connected to the second data line D2 through an eighth conductive pattern CP8.

The eighth conductive pattern CP8 may be formed of a third conductive layer provided and/or formed on the interlayer insulating layer ILD. An end portion of the eighth conductive pattern CP8 may be electrically connected to the second data line D2 through a contact hole sequentially penetrating the buffer layer BFL, the gate insulating layer GI, and the interlayer insulating layer ILD. The other end portion of the eighth conductive pattern CP8 may be electrically connected to the second drain region DE2 through a contact hole sequentially penetrating the gate insulating layer GI and the interlayer insulating layer ILD.

The third transistor T3 may include a third gate electrode GE3, a third active pattern ACT3, the third source region SE3, and a third drain region DE3.

The third gate electrode GE3 may be integral with the connection line CNL, and be connected to the first scan line S1.

The third active pattern ACT3 may be a channel region of the third transistor T3.

The third source region SE3 may be connected to the third active pattern ACT3. The third source region SE3 may be electrically connected to the second lower conductive layer BML2.

The third drain region DE3 may be connected to the third active pattern ACT3. The third drain region DE3 may be connected to the initialization power line IPL through the fifth conductive pattern CP5.

The second storage capacitor Cst2 may have a structure identical or substantially similar to the structure of the first storage capacitor Cst1 of the above-described first pixel circuit PXC1. In an example, the second storage capacitor Cst2 may include a second lower electrode LE2 and the second upper electrode UE2.

The second lower electrode LE2 may be the second conductive layer, and be integral with a corresponding transistor, e.g., the second gate electrode GE2 of the second transistor T2. The second upper electrode UE2 may be the third conductive layer, and overlap the second lower electrode LE2. The second upper electrode UE2 may be electrically connected to the second lower conductive layer BML2 through a contact hole.

As described above, the second upper electrode UE2 may be electrically connected to each of the first source region SE1 and the third source region SE3 through the second lower conductive layer BML2.

The third pixel circuit PXC3 may include the first transistor T1, the second transistor T2, and the third transistor T3, and the third storage capacitor Cst3.

The first transistor T1 may include a first gate electrode GE1, a first active pattern ACT1, a first source region SE1, and a first drain region DE1.

The first gate electrode GE1 may be connected to a second source region SE2 of the second transistor T2.

The first active pattern ACT1 may be a channel region of the first transistor T1.

The first source region SE1 may be connected to the first active pattern ACT1. The first source region SE1 may be electrically connected to a third lower conductive layer BML3 through a contact hole penetrating the buffer layer BFL.

The third lower conductive layer BML3 may be a component corresponding to each of the first and second lower conductive layers BML1 and BML2. The third lower conductive layer BML3 may be formed of the first conductive layer. The third lower conductive layer BML3 may be electrically connected to the first source region SE1 through a contact hole. The third lower conductive layer BML3 may be electrically connected to a third source region SE3 of the third transistor T3 through a contact hole penetrating the buffer layer BFL. For example, the third lower conductive layer BML3 may be electrically connected to a third upper electrode UE3 of the third storage capacitor Cst3 through a contact hole sequentially penetrating the buffer layer BFL, the gate insulating layer GI, and the interlayer insulating layer ILD.

The first drain region DE1 may be connected to the first active pattern ACT1. The first drain region DE1 may be electrically connected to the first layer FL of the first power line PL1 through a contact hole penetrating the buffer layer BFL.

The second transistor T2 may include a second gate electrode GE2, a second active pattern ACT2, the second source region SE2, and a second drain region DE2.

The second gate electrode GE2 may be integral with the connection line CNL to be connected to the first scan line S1.

The second active pattern ACT2 may be a channel region of the second transistor T2.

The second source region SE2 may be connected to the second active pattern ACT2. The second source region SE2 may be connected to the first gate electrode GE1 through a fourth conductive pattern CP4.

The fourth conductive pattern CP4 may be formed of the third conductive layer provided and/or formed on the interlayer insulating layer ILD. An end portion of the fourth conductive pattern CP4 may be electrically connected to the second source region SE2 through a contact hole sequentially penetrating the gate insulating layer GI and the interlayer insulating layer ILD. The other end portion of the fourth conductive pattern CP4 may be connected to the first gate electrode GE1 through a contact hole penetrating the interlayer insulating layer ILD. Accordingly, the first gate electrode GE1 and the second source region SE2 may be connected to each other through the fourth conductive pattern CP4.

The second drain region DE2 may be connected to the second active pattern ACT2. The second drain region DE2 may be connected to the third data line D3 through a sixth conductive pattern CP6.

The sixth conductive pattern CP6 may be formed of the third conductive layer provided and/or formed on the interlayer insulating layer ILD. An end portion of the sixth conductive pattern CP6 may be electrically connected to the third data line D3 through a contact hole sequentially penetrating the buffer layer BFL, the gate insulating layer GI, and the interlayer insulating layer ILD. The other end portion of the sixth conductive pattern CP6 may be electrically connected to the second drain region DE2 through a contact hole sequentially penetrating the gate insulating layer GI and the interlayer insulating layer ILD. Accordingly, the second drain region DE2 and the third data line D3 may be connected to each other through the sixth conductive pattern CP6.

The third transistor T3 may include a third gate electrode GE3, a third active pattern ACT3, the third source region SE3, and a third drain region DE3.

The third gate electrode GE3 may be integral with the connection line CNL, and be connected to the first scan line S1.

The third active pattern ACT3 may be a channel region of the third transistor T3.

The third source region SE3 may be connected to the third active pattern ACT3. The third source region SE3 may be electrically connected to the third lower conductive layer BML3 through a contact hole.

The third drain region DE3 may be connected to the third active pattern ACT3. The third drain region DE3 may be connected to the initialization power line IPL through the fifth conductive pattern CP5. In an embodiment, the third drain region DE3 of the third transistor T3 and the second drain region DE2 of the second transistor T2 may share the fifth conductive pattern CP5.

The third storage capacitor Cst3 may have a structure identical or substantially similar to the structure of each of the first and second storage capacitors Cst1 and Cst2. In an example, the third storage capacitor Cst3 may include a third lower electrode LE3 and the third upper electrode UE3.

The third lower electrode LE3 may be the second conductive layer, and be integral with a corresponding transistor, e.g., the third gate electrode GE3 of the third transistor T3. The third upper electrode UE3 may be the third conductive layer, and overlap the third lower electrode LE3. The third upper electrode UE3 may be electrically connected to the third lower conductive layer BML3 through a contact hole.

As described above, the third upper electrode UE3 may be electrically connected to each of the first source region SE1 and the third source region SE3 through the third lower conductive layer BML3.

Referring to FIGS. 6 to 8, each pixel PXL may include an emission area EA and a non-emission area NEA. The emission area EA may be an area including light emitting elements LD to emit light. The non-emission area NEA may surround the emission area EA. The non-emission area NEA may be an area in which a bank BNK surrounding the emission area EA is provided. The bank BNK may be provided (or disposed) in the non-emission area NEA to at least partially surround the emission area EA.

The bank BNK may include an opening overlapping the emission area EA. The opening of the bank BNK may provide a space in which light emitting elements LD are provided (or disposed) in a process of supplying the light emitting elements LD to each pixel PXL. For example, a designed kind and/or a designed amount of light emitting element ink may be supplied to the space partitioned by the opening of the bank BNK.

The bank BNK may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the bank BNK may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In some embodiments, the bank BNK may include at least one light blocking material and/or at least one reflective material. Accordingly, light leakage between adjacent pixels PXL may be prevented. For example, the bank BNK may include at least one black pigment.

Each pixel PXL may include defining walls (or partition walls) WL, electrodes ALE, light emitting elements LD, and/or connection electrodes ELT.

The defining walls WL may overlap the emission area EA and be spaced apart from each other. The defining walls WL may be at least partially disposed in the non-emission area NEA. The defining walls WL may extend along the second direction (e.g., Y-axis direction), and be spaced apart from each other along the first direction (e.g., X-axis direction).

Each of the defining walls WL may partially overlap at least one electrode ALE in at least the emission area EA. For example, the defining walls WL may be provided on the bottom surface of the electrodes ALE. As the defining wall WL is provided on the bottom surface of an area of each of the electrodes ALE, the area of each of the electrodes ALE may protrude in an upper direction, i.e., a third direction (e.g., Z-axis direction) in an area in which the defining wall WL is formed. In case that the defining walls WL and/or the electrodes ALE include a reflective material, a reflective wall structure may be formed at the periphery of the light emitting elements LD. Accordingly, light emitted from the light emitting elements LD may be emitted in the upper direction of the pixel PXL (e.g., a front direction of the display panel PNL, including a viewing angle range), and thus light emission efficiency of the display panel PNL may be improved.

The electrodes ALE may be provided (or disposed) in at least the emission area EA. The electrode ALE may extend along the second direction (e.g., Y-axis direction), and be spaced apart from each other along the first direction (e.g., X-axis direction).

Each of first to third electrodes ALE1, ALE2, and ALE3 may extend along the second direction (e.g., Y-axis direction), and the first to third electrodes ALE1, ALE2, and ALE3 may be spaced apart from each other along the first direction (e.g., X-axis direction) to be sequentially disposed.

A pair of electrodes ALE adjacent to each other may receive different alignment voltages in a process of aligning the light emitting elements LD. For example, in case that the first to third electrodes ALE1, ALE2, and ALE3 are sequentially arranged along the first direction (e.g., X-axis direction), the first electrode ALE1 and the second electrode ALE2 may receive different alignment voltages, and the second electrode ALE2 and the third electrode ALE3 may receive different alignment voltages.

Each of the light emitting elements LD may be aligned between a pair of electrodes ALE in the emission area EA. Each of the light emitting elements LD may be electrically connected between a pair of connection electrodes ELT.

A first light emitting element LD1 may be aligned between the first and second electrodes ALE1 and ALE2. The first light emitting element LD1 may be electrically connected between a first connection electrode ELT1 and a second connection electrode ELT2. In an example, the first light emitting element LD1 may be aligned in a first area (e.g., an upper end area) of the first and second electrodes ALE1 and ALE2. A first end portion EP1 of the first light emitting element LD1 may be electrically connected to the first connection electrode ELT1, and a second end portion EP2 of the first light emitting element LD1 may be electrically connected to the second connection electrode ELT2.

A second light emitting element LD2 may be aligned between the first and second electrodes ALE1 and ALE2. The second light emitting element LD2 may be electrically connected between the second connection electrode ELT2 and a third connection electrode ELT3. In an example, the second light emitting element LD2 may be aligned in a second area (e.g., a lower end area) of the first and second electrodes ALE1 and ALE2. A first end portion EP1 of the second light emitting element LD2 may be electrically connected to the second connection electrode ELT2, and a second end portion EP2 of the second light emitting element LD2 may be electrically connected to the third connection electrode ELT3.

A third light emitting element LD3 may be aligned between the second and third electrodes ALE2 and ALE3. The third light emitting element LD3 may be electrically connected between the third connection electrode ELT3 and a fourth connection electrode ELT4. In an example, the third light emitting element LD3 may be aligned in a second area (e.g., a lower end area) of the second and third electrodes ALE2 and ALE3. A first end portion EP1 of the third light emitting element LD3 may be electrically connected to the third connection electrode ELT3, and a second end portion EP2 of the third light emitting element LD3 may be electrically connected to the fourth connection electrode ELT4.

A fourth light emitting element LD4 may be aligned between the second and third electrodes ALE2 and ALE3. The fourth light emitting element LD4 may be electrically connected between the fourth connection electrode ELT4 and a fifth connection electrode ELT5. In an example, the fourth light emitting element LD4 may be aligned in a first area (e.g., an upper end area) of the second and third electrodes ALE2 and ALE3. A first end portion EP1 of the fourth light emitting element LD4 may be electrically connected to the fourth connection electrode ELT4, and a second end portion EP2 of the fourth light emitting element LD4 may be electrically connected to the fifth connection electrode ELT5.

In an example, the first light emitting element LD1 may be disposed in a left upper end area of the emission area EA, and the second light emitting element LD2 may be disposed in a left lower end area of the emission area EA. The third light emitting elements LD3 may be disposed at a right lower end area of the emission area EA, and the fourth light emitting element LD4 may be disposed in a right upper end area of the emission area EA. However, the arrangement and/or connection structure of the light emitting elements LD may be variously changed according to the structure of the light emitting unit EMU and/or the number of serial stages.

Each of the connection electrodes ELT may be provided (or disposed) in at least the emission area EA, and overlap at least one electrode ALE and/or at least one light emitting element LD. For example, each of the connection electrodes ELT may be formed on the electrodes ALE and/or the light emitting elements LD to overlap the electrodes ALE and/or the light emitting elements LD. Therefore, each of the connection electrodes ELT may be electrically connected to the light emitting elements LD.

The first connection electrode ELT1 may be disposed on a first area (e.g., an upper end area) of the first electrode ALE1 and the first end portions EP1 of the first light emitting elements LD1, to be electrically connected to the first end portions EP1 of the first light emitting elements LD1.

The second connection electrode ELT2 may be disposed on a first area (e.g., an upper end area) of the second electrode ALE2 and the second end portions EP2 of the first light emitting elements LD1, to be electrically connected to the second end portions EP2 of the first light emitting elements LD1. Also, the second connection electrode ELT2 may be disposed on a second area (e.g., a lower end area) of the first electrode ALE1 and the first end portions EP1 of the second light emitting elements LD2, to be electrically connected to the first end portions EP1 of the second light emitting elements LD2. For example, the second connection electrode ELT2 may electrically connect the second end portions EP2 of the first light emitting elements LD1 and the first end portions EP1 of the second light emitting elements LD2 to each other in the emission area EA. For example, the second connection electrode ELT2 may have a bent shape. For example, the second connection electrode ELT2 may have a structure bent or curved at a boundary between an area in which at least one first light emitting element LD1 is arranged and an area in which at least one second light emitting element LD2 is arranged.

The third connection electrode ELT3 may be disposed on a second area (e.g., a lower end area) of the second electrode ALE2 and the second end portions EP2 of the second light emitting elements LD2, to be electrically connected to the second end portions EP2 of the second light emitting elements LD2. Also, the third connection electrode ELT3 may be disposed on a second area (e.g., a lower end area) of the third electrode ALE3 and the first end portions EP1 of the third light emitting elements LD3, to be electrically connected to the first end portions EP1 of the third light emitting elements LD3. For example, the third connection electrode ELT3 may electrically connect the second end portions EP2 of the second light emitting elements LD2 and the first end portions EP1 of the third light emitting elements LD3 to each other in the emission area EA. For example, the third connection electrode ELT3 may have a bent shape. For example, the third connection electrode ELT3 may have a structure bent or curved at a boundary between an area in which at least one second light emitting element LD2 is arranged and an area in which at least one third light emitting element LD3 is arranged.

The fourth connection electrode ELT4 may be disposed on the second area (e.g., the lower end area) of the second electrode ALE2 and the second end portions EP2 of the third light emitting elements LD3, to be electrically connected to the second end portions EP2 of the third light emitting elements LD3. Also, the fourth connection electrode ELT4 may be disposed on a first area (e.g., an upper end area) of the third electrode ALE3 and the first end portions EP1 of the fourth light emitting elements LD4, to be electrically connected to the first end portions EP1 of the fourth light emitting elements LD4. For example, the fourth connection electrode ELT4 may electrically connect the second end portions EP2 of the third light emitting elements LD3 and the first end portions EP1 of the fourth light emitting elements LD4 to each other in the emission area EA. For example, the fourth connection electrode ELT4 may have a bent shape. For example, the fourth connection electrode ELT4 may have a structure bent or curved at a boundary between an area in which at least one third light emitting element LD3 is arranged and an area in which at least one fourth light emitting element LD4 is arranged.

The fifth connection electrode ELT5 may be disposed on the first area (e.g., the upper end area) of the second electrode ALE2 and the second end portions EP2 of the fourth light emitting elements LD4, to be electrically connected to the second end portions EP2 of the fourth light emitting elements LD4.

The first connection electrode ELT1, the third connection electrode ELT3, and/or the fifth connection electrode ELT5 may be formed of the same conductive layer. The second connection electrode ELT2 and the fourth connection electrode ELT4 may be formed of the same conductive layer. In an example, the connection electrodes ELT may be formed of conductive layers as shown in FIG. 7. For example, the first connection electrode ELT1, the third connection electrode ELT3, and/or the fifth connection electrode ELT5 may be formed of a fifth conductive layer, and the second connection electrode ELT2 and the fourth connection electrode ELT4 may be formed a sixth conductive layer different from the fifth conductive layer. In another example, the first to fifth connection electrodes ELT1, ELT2, ELT3, ELT4, and ELT5 may be formed of the same conductive layer as shown in FIG. 8.

In the above-described manner, the light emitting elements LD aligned between the electrodes ALE may be connected in a designed form by using the connection electrodes ELT. For example, the first light emitting elements LD1, the second light emitting elements LD2, the third light emitting elements LD3, and the fourth light emitting elements LD4 may be sequentially connected in series by using the connection electrodes ELT.

Hereinafter, a sectional structure of the pixel PXL will be described in detail with reference to FIGS. 9 to 14. In FIGS. 9, 10, and 13, the first transistor T1 among various circuit elements of the pixel circuit (PXC shown in FIG. 4) is illustrated. The first transistor T1 among the first to third transistors T3 will be representatively described, and the second and third transistors T2 and T3 will be described. The structure of the first transistor T1 and/or the position of the first transistor T1 for each layer are/is not limited to the embodiment shown in FIGS. 9, 10, and 13, and may be variously changed in some embodiments.

Each pixel PXL in accordance with an embodiment may include circuit elements including the first transistor T1 disposed on a base layer BSL and various lines connected thereto. Electrodes ALE, light emitting elements LD, and/or connection electrodes ELT, which form a light emitting unit EMU, may be disposed above the circuit elements.

The base layer BSL may be used to form a base member, and may be a rigid or flexible substrate or a film. In an example, the base layer BSL may be a rigid substrate made of glass or tempered glass, a flexible substrate (or thin film) made of a plastic or metal material, or at least one insulating layer. The material and/or property of the base layer BSL is not limited thereto. In an embodiment, the base layer BSL may be substantially transparent. The term “substantially transparent” may mean that light is transmitted with a certain transmittance or more. In another embodiment, the base layer BSL may be translucent or opaque. Also, the base layer BSL may include a reflective material in some embodiments.

A first lower conductive layer BML1 and a vertical power line PL2_1 of a second power line PL2 may be disposed on the base layer BSL. The first lower conductive layer BML1 and the vertical power line PL2_1 may be disposed in (or formed as) the same layer. For example, the first lower conductive layer BML1 and the vertical power line PL2_1 may be simultaneously formed by the same process, but embodiments are not limited thereto.

Each of the first lower conductive layer BML1 and the vertical power line PL2_1 may be formed as a single layer or a multi-layer, which is made of molybdenum (Mo), copper (Cu), aluminum (Al), chromium (Cr), gold (Au), titanium (Ti), nickel (Ni), neodymium (Nd), indium (In), tin (Sn), and any oxide or ally thereof.

A buffer layer BFL may be disposed over the first lower conductive layer BML1 and the vertical power line PL2_1. The buffer layer BFL may prevent an impurity from being diffused into each circuit element. The buffer layer BFL may be formed as a single layer, but be formed as a multi-layer including at least two layers. In case that the buffer layer BFL is provided as the multi-layer, the layers may be formed of the same material or be formed of different materials.

A first active pattern ACT1 may be disposed on the buffer layer BFL. The first active pattern ACT1 may be made of poly-silicon, amorphous silicon, an oxide semiconductor, or the like.

A gate insulating layer GI may be disposed on the buffer layer BFL and the first active pattern ACT1. In an example, the gate insulating layer GI may be disposed between the first active pattern and a first gate electrode GE1 of the first transistor T1. The gate insulating layer GI may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first gate electrode GE1 of the first transistor T1 may be disposed on the gate insulating layer GI. The first gate electrode GE1 may be disposed on the gate insulating layer GI to overlap the first active pattern ACT1 in the third direction (e.g., Z-axis direction).

The first gate electrode GE1 may be formed as a single layer or a multi-layer, which is made of molybdenum (Mo), copper (Cu), aluminum (Al), chromium (Cr), gold (Au), titanium (Ti), nickel (Ni), neodymium (Nd), indium (In), tin (Sn), and any oxide or ally thereof. For example, the first gate electrode GE1 may be formed as a multi-layer in which titanium (Ti), copper (Cu), and/or indium tin oxide (ITO) are sequentially or repeatedly stacked.

An interlayer insulating layer ILD may be disposed over the first gate electrode GE1. In an example, the interlayer insulating layer ILD may be disposed between the first gate electrode GE1 and first and second transistor electrodes TE1 and TE2.

The interlayer insulating layer ILD may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The first and second transistor electrodes TE1 and TE2 of the first transistor T1 and a horizontal power line PL2_2 of the second power line PL2 may be disposed on the interlayer insulating layer ILD. The first and second transistor electrodes TE1 and TE2 and a horizontal power line PL2_2 may be disposed in (or formed as) the same layer. For example, the first and second transistor electrodes TE1 and TE2 and a horizontal power line PL2_2 may be simultaneously formed by the same process, but embodiments are not limited thereto.

The first and second transistor electrodes TE1 and TE2 may overlap the first active pattern ACT1 in the third direction (e.g., Z-axis direction). The first and second transistor electrodes TE1 and TE2 may be electrically connected to the first active pattern ACT1. For example, the first transistor electrode TE1 may be electrically connected to a region (e.g., first source region) of the first active pattern ACT1 through a contact hole penetrating the interlayer insulating layer ILD. The first transistor electrode TE1 may be electrically connected to the first lower conductive layer BML1 through a contact hole penetrating the interlayer insulating layer ILD and the buffer layer BFL. The second transistor electrode TE2 may be electrically connected to the other region (e.g., first drain region) of the first active pattern through a contact hole penetrating the interlayer insulating layer ILD.

The horizontal power line PL2_2 may overlap the vertical power line PL2_1 in the third direction (e.g., Z-axis direction). The horizontal power line PL2_2 may be electrically connected to the vertical power line PL2_1. For example, the horizontal power line PL2_2 may be electrically connected to the vertical power line PL2_1 through a contact hole penetrating the interlayer insulating layer ILD and the buffer layer BFL.

The first and second transistor electrodes TE1 and TE2 and the horizontal power line PL2_2 may be formed as a single layer or a multi-layer, which is made of molybdenum (Mo), copper (Cu), aluminum (Al), chromium (Cr), gold (Au), titanium (Ti), nickel (Ni), neodymium (Nd), indium (In), tin (Sn), and any oxide or ally thereof.

A protective layer PSV may be disposed over the first and second transistor electrodes TE1 and TE2 and the horizontal power line PL2_2. The protective layer PSV may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A via layer VIA may be disposed on the protective layer PSV. The via layer VIA may be made of an organic material to planarize a lower step difference. For example, the via layer VIA may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the via layer VIA may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

Defining walls WL may be disposed on the via layer VIA. The defining walls WL may function to form a step difference such that the light emitting elements LD may be readily aligned in the emission area EA.

In some embodiments, the defining walls WL may have various shapes. In an embodiment, the defining walls WL may have a shape protruding in the third direction (e.g., Z-axis direction) on the base layer BSL. The defining walls WL may be formed to have an inclined surface inclined at a certain angle with respect to the base layer BSL. However, embodiments are not limited thereto, and the defining walls WL may have a sidewall having a curved shape, a stepped shape, or the like. In an example, the defining walls WL may have a section having a semicircular shape, a semi-elliptical shape, or the like.

The defining walls WL may include at least one organic material and/or at least one inorganic material. In an example, the defining walls WL may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the defining walls WL may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The electrodes ALE may be disposed on the via layer VIA and the defining walls WL. The electrodes ALE may at least partially cover side surfaces and/or top surfaces of the defining walls WL. The electrodes ALE disposed on the top surface of the defining walls WL may have a shape corresponding to the defining wall WL. In an example, the electrodes ALE disposed on the defining walls WL may include an inclined surface or a curved surface, which has a shape corresponding to the shape of the defining walls WL. The defining walls WL and the electrodes ALE may function a reflective member, and reflects light emitted from the light emitting elements LD and guides the reflected light in a front direction of the pixel PXL, i.e., the third direction (e.g., Z-axis direction). Thus, the light emission efficiency of the display panel PNL may be improved.

The electrodes ALE may be spaced apart from each other. The electrodes ALE may be disposed in (or formed as) the same layer. For example, the electrodes ALE may be simultaneously formed by the same process, but embodiments are not limited thereto.

The electrodes ALE may receive an alignment voltage from the above-described alignment pad (AP shown in FIG. 3) in a step of aligning light emitting elements LD. Accordingly, an electric field may be formed between the electrodes ALE, so that light emitting elements LD provided (or disposed) in each pixel PXL may be biasedly aligned between the electrodes ALE. In an embodiment, in order to improve an alignment degree of the light emitting elements LD, the signal lines described with reference to FIG. 5 along with the electrodes ALE may receive the alignment voltage. This will be described in detail later with reference to FIGS. 17 to 34.

The electrodes ALE may include at least one conductive material. In an example, the electrodes ALE may include at least one metal or any alloy including the same among various metallic materials including silver (Ag), magnesium (Mg), aluminum (Al), platinum (Pt), palladium (Pd), gold (Au), nickel (Ni), neodymium (Nd), iridium (Ir), chromium (Cr), titanium (Ti), molybdenum (Mo), copper (Cu), and the like, at least one conductive oxide such as Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), Gallium Tin Oxide (GTO), and Fluorine doped Tin Oxide (FTO), and at least one conductive material among conductive polymers such as PEDOT, but embodiments are not limited thereto.

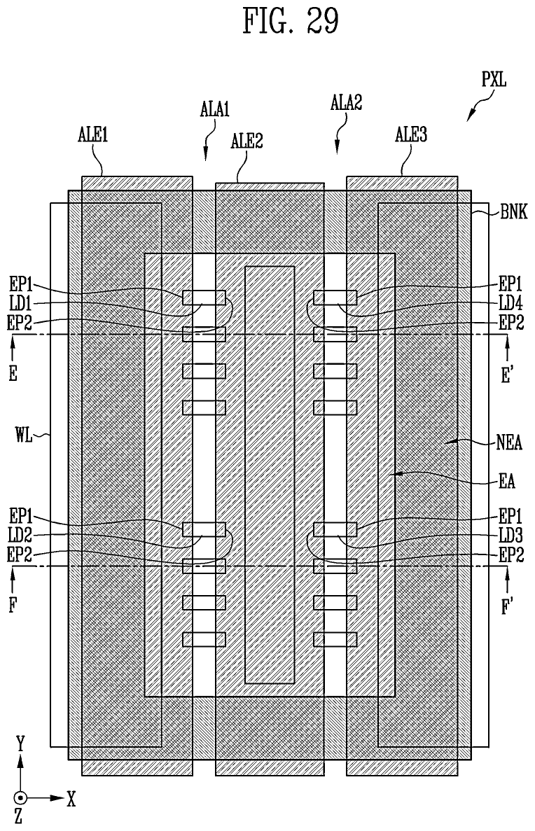

In an embodiment, as shown in FIGS. 10 and 12, an electrode layer MTL may be further disposed below the electrodes ALE. The electrode layer MTL may overlap an alignment area in which the light emitting elements LD are aligned. The electrode layer MTL may at least partially overlap the electrodes ALE. The electrode layer MTL may be electrically separated from the electrodes ALE. In an embodiment, in order to improve the alignment degree of the light emitting elements LD, the electrode layer MTL along with the electrodes ALE may receive the alignment voltage in the step of aligning the light emitting elements LD. This will be described in detail with reference to FIGS. 29 to 34.

The electrode layer MTL may be formed of the fourth conductive layer provided on the protective layer PSV. The fourth conductive layer and the third conductive layer may include the same material. The fourth conductive layer may include at least one material selected from the materials such as the material of the third conductive layer. A second interlayer insulating layer ILD2 may be further disposed between the electrode layer MTL and the electrodes ALE. The second interlayer insulating layer ILD2 may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A first insulating layer INS1 may be disposed over the electrodes ALE. The first insulating layer INS1 may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

A bank BNK may be disposed on the first insulating layer INS1. An opening of the bank BNK may provide a space in which light emitting elements LD are provided (or disposed) in a step of supplying the light emitting elements LD to each of the pixels PXL. For example, a designed kind and/or a designed amount of light emitting element ink may be supplied to the space partitioned by the opening of the bank BNK.

The bank BNK may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the bank BNK may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The light emitting elements LD may be disposed between the electrodes ALE. The light emitting elements LD may be provided (or disposed) in the opening of the bank BNK to be disposed between the defining walls WL.

The light emitting elements LD may be prepared in a form in which the light emitting elements LD are dispersed in a light emitting element ink, to be supplied to each of the pixels PXL through an inkjet printing process, or the like. In an example, the light emitting elements LD may be dispersed in a volatile solvent to be provided to each pixel PXL. Subsequently, in case that an alignment voltage is supplied through the electrodes ALE, the light emitting elements LD may be aligned between the electrodes ALE, in case that an electric field is formed between the electrodes ALE. After the light emitting elements LD are aligned, the solvent may be volatilized or removed through other processes, so that the light emitting elements LD may be stably arranged between the electrodes ALE.

A second insulating layer INS2 may be disposed on the light emitting elements LD. For example, the second insulating layer INS2 may be partially provided on the light emitting elements LD, and expose first and second end portions EP1 and EP2 of the light emitting elements LD. In case that the second insulating layer INS2 is formed on the light emitting elements LD after the alignment of the light emitting elements LD is completed, the light emitting elements LD may be prevented from being separated from positions at which the light emitting elements LD are aligned.

The second insulating layer INS2 may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The connection electrodes ELT may be disposed on the first and second end portions EP1 and EP2 of the light emitting elements LD, which are exposed by the second insulating layer INS2. A first connection electrode ELT1 may be disposed (e.g., directly disposed) on first end portions EP1 of first light emitting elements LD1, to be in contact with the first end portions EP1 of the first light emitting elements LD1.

A second connection electrode ELT2 may be disposed (e.g., directly disposed) on second end portions EP2 of the first light emitting elements LD1, to be in contact with the second end portions EP2 of the first light emitting elements LD1. The second connection electrode ELT2 may be disposed (e.g., directly disposed) on first end portions EP1 of second light emitting elements LD2, to be in contact with the first end portions EP1 of the second light emitting elements LD2. For example, the second connection electrode ELT2 may electrically connect the second end portions EP2 of the first light emitting elements LD1 and the first end portions EP1 of the second light emitting elements LD2 to each other.

For example, a third connection electrode ELT3 may be disposed (e.g., directly disposed) on second end portions EP2 of the second light emitting elements LD2, to be in contact with the second end portions EP2 of the second light emitting elements LD2. The third connection electrode ELT3 may be disposed (e.g., directly disposed) on first end portions EP1 of third light emitting elements LD3, to be in contact with the first end portions EP1 of the third light emitting elements LD3. For example, the third connection electrode ELT3 may electrically connect the second end portions EP2 of the second light emitting elements LD2 and the first end portions EP1 of the third light emitting elements LD3 to each other.

For example, a fourth connection electrode ELT4 may be disposed (e.g., directly disposed) on second end portions EP2 of the third light emitting elements LD3, to be in contact with the second end portions EP2 of the third light emitting elements LD3. The fourth connection electrode ELT4 may be disposed (e.g., directly disposed) on first end portions EP1 of fourth light emitting elements LD4, to be in contact with the first end portions EP1 of the fourth light emitting elements LD4. For example, the fourth connection electrode ELT4 may electrically connect the second end portions EP2 of the third light emitting elements LD3 and the first end portions EP1 of the fourth light emitting elements LD4 to each other.

For example, a fifth connection electrode ELT5 may be disposed (e.g., directly disposed) on second end portions EP2 of the fourth light emitting elements LD4, to be in contact with the second end portions EP2 of the fourth light emitting elements LD4.

The first connection electrode ELT1 may be electrically connected to the first transistor electrode TE1 of the first transistor T1 through a contact hole penetrating the first insulating layer INS1, the via layer VIA, and the protective layer PSV. The fifth connection electrode ELT5 may be electrically connected to the horizontal power line PL2_2 through a contact hole penetrating the first insulating layer INS1, the via layer VIA, and the protective layer PSV.

In an embodiment, the connection electrodes ELT may be formed of conductive layers. For example, the first connection electrode ELT1, the third connection electrode ELT3, and the fifth connection electrode ELT5 may be disposed in (or formed as) the same layer (e.g., fifth conductive layer) as shown in FIGS. 9 to 12. The second connection electrode ELT2 and the fourth connection electrode ELT4 may be disposed in (or formed as) the same layer (e.g., sixth conductive layer). The first connection electrode ELT1, the third connection electrode ELT3, and the fifth connection electrode ELT5 may be disposed on the second insulating layer INS2. A third insulating layer INS3 may be disposed over the first connection electrode ELT1, the third connection electrode ELT3, and the fifth connection electrode ELT5. The second connection electrode ELT2 and the fourth connection electrode ELT4 may be disposed on the third insulating layer INS3. As such, in case that the third insulating layer INS3 is disposed between the connection electrodes ELT formed as different conductive layers, the connection electrodes ELT may be stably separated from each other by the third insulating layer INS3, and thus the electrical stability between the first and second end portions EP1 and EP2 of the light emitting elements LD may be ensured.

The third insulating layer INS3 may be formed as a single layer or a multi-layer, and include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

In another embodiment, the connection electrodes ELT may be formed as the same conductive layer. For example, the first to fifth connection electrodes ELT1, ELT2, ELT3, ELT4, and ELT5 may be disposed in (or formed as) the same layer as shown in FIGS. 13 and 14. In an example, the first to fifth connection electrodes ELT1, ELT2, ELT3, ELT4, and ELT5 may be simultaneously formed by the same process. As such, in case that the connection electrodes ELT are simultaneously formed, the number of masks may be decreased, and a manufacturing process may be simplified.

The connection electrodes ELT may be made of various transparent conductive materials. In an example, the connection electrodes ELT may include at least one of various transparent conductive materials including Indium Tin Oxide (ITO), Indium Zinc Oxide (IZO), Indium Tin Zinc Oxide (ITZO), Zinc Oxide (ZnO), Aluminum doped Zinc Oxide (AZO), Gallium doped Zinc Oxide (GZO), Zinc Tin Oxide (ZTO), Gallium Tin Oxide (GTO), and Fluorine doped Tin Oxide (FTO), and be implemented substantially transparently or translucently to satisfy a selected transmittance. Accordingly, light emitted from the first and second end portions EP1 and EP2 of the light emitting elements LD may be emitted to the outside of the display panel PNL with passing through the connection electrodes ELT.

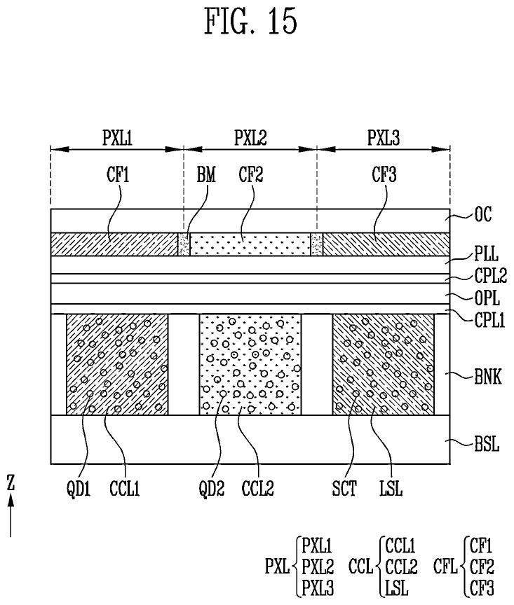

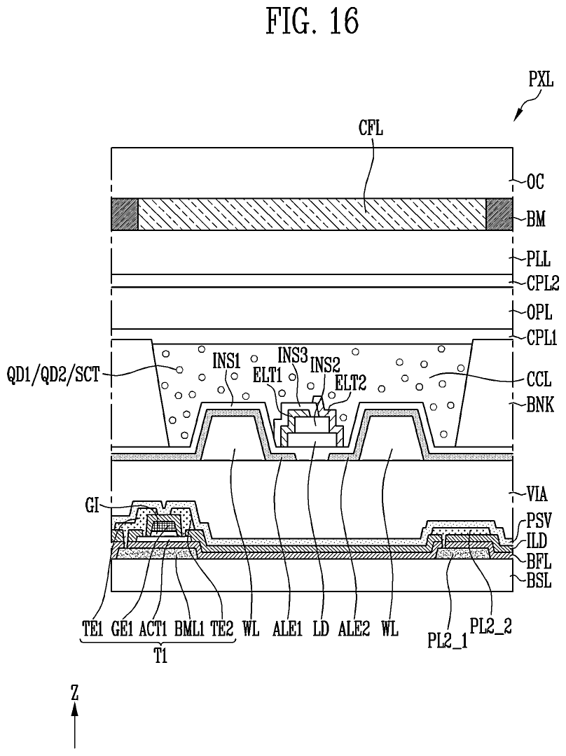

FIG. 15 is a schematic cross-sectional view illustrating first to third pixels in accordance with an embodiment. FIG. 16 is a schematic cross-sectional view illustrating a pixel in accordance with an embodiment.

FIG. 15 illustrates a color conversion layer CCL, an optical layer OPL, and/or a color filter layer CFL. In FIG. 15, for convenience of description, the components except for the base layer BSL and the bank BNK, which are shown in FIGS. 9 to 14, will be omitted. FIG. 16 illustrates in detail a stacked structure of a pixel PXL in relation to the color conversion layer CCL, the optical layer OPL, and/or the color filter layer CFL.

Referring to FIGS. 15 and 16, the bank BNK may be disposed between first to third pixels PXL1, PXL2, and PXL3 or at a boundary of the first to third pixels PXL1, PXL2, and PXL3, and include an opening overlapping each of the first to third pixels PXL1, PXL2, and PXL3. The opening of the bank BNK may provide a space in which the color conversion layer CCL may be provided.

The color conversion layer CCL may be disposed over light emitting elements LD in the opening of the bank BNK. The color conversion layer CCL may include a first color conversion layer CCL1 disposed in the first pixel PXL1, a second color conversion layer CCL2 disposed in the second pixel PXL2, and a light scattering layer LSL disposed in the third pixel PXL3.

The first color conversion layer CCL1 may include first color conversion particles for converting light of the third color, which is emitted from the light emitting element LD, into light of a first color. For example, the first color conversion layer CCL1 may include first quantum dots QD1 dispersed in a matrix material such as base resin.

In an embodiment, in case that the light emitting element LD is a blue light emitting element emitting blue light, and the first pixel PXL1 is a red pixel, the first color conversion layer CCL1 may include a first quantum dot QD1 for converting blue light, which is emitted from the blue light emitting element, into red light. The first quantum dot QD1 may absorb blue light and emit red light by shifting a wavelength of the blue light according to energy transition. For example, in case that the first pixel PXL1 is a pixel of another color, the first color conversion layer CCL1 may include a first quantum dot QD1 corresponding to the color of the first pixel PXL1.

The second color conversion layer CCL2 may include second color conversion particles for converting light of the third color, which is emitted from the light emitting element LD, into light of a second color. For example, the second color conversion layer CCL2 may include second quantum dots QD2 dispersed in a matrix material such as base resin.

In an embodiment, in case that the light emitting element LD is a blue light emitting element emitting blue light, and the second pixel PXL2 is a green pixel, the second color conversion layer CCL2 may include a second quantum dot QD2 for converting blue light, which is emitted from the blue light emitting element, into light of green. The second quantum dot QD2 may absorb blue light and emit green light by shifting a wavelength of the blue light according to energy transition. For example, in case that the second pixel PXL2 is a pixel of another color, the second color conversion layer CCL2 may include a second quantum dot QD2 corresponding to the color of the second pixel PXL2.

In an embodiment, blue light having a relatively short wavelength in a visible light band may be incident into the first quantum dot QD1 and the second quantum dot QD2, so that absorption coefficients of the first quantum dot QD1 and the second quantum dot QD2 may be increased. Accordingly, the efficiency of light finally emitted from the first pixel PXL1 and the second pixel PXL2 may be improved, and excellent color reproduction may be ensured. The light emitting unit EMU of each of the first to third pixels PXL1, PXL2, and PXL3 may be formed by using light emitting elements of the same color (e.g., blue light emitting elements), so that the manufacturing efficiency of the display device may be improved.

The light scattering layer LSL may be provided to efficiently use light of the third color (or blue) emitted from the light emitting element LD. In an example, in case that the light emitting element LD is a blue light emitting element emitting blue light, and the third pixel PXL3 is a blue pixel, the light scattering layer LSL may include at least one kind of light scattering particle SCT to efficiently use light emitted from the light emitting element LD. In an example, the light scattering particle SCT of the light scattering layer LSL may include at least one of barium sulfate (BaSO₄), calcium carbonate (CaCO₃), titanium oxide (TiO₂), silicon oxide (SiO₂), silicon nitride (Si₃N₄), aluminum oxide (Al₂O₃), zirconium oxide (ZrO₂), and zinc oxide (ZnO). For example, the light scattering particle SCT is not disposed only in the third pixel PXL3, and may be selectively included in the first color conversion layer CCL1 or the second color conversion layer CCL2. In some embodiments, the light scattering particle SCT may be omitted such that the light scattering layer LSL formed of transparent polymer is provided.

A first capping layer CPL1 may be disposed on the color conversion layer CCL. The first capping layer CPL1 may be provided (or disposed) through the first to third pixels PXL1, PXL2, and PXL3. The first capping layer CPL1 may cover the color conversion layer CCL. The first capping layer CPL1 may protect the color conversion layer CCL from being damaged or contaminated due to infiltration (or permeation) of an impurity such as moisture or air from the outside.

The first capping layer CPL1 may be an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like.

The optical layer OPL may be disposed on the first capping layer CPL1. The optical layer OPL may function to improve light extraction efficiency by recycling light provided from the color conversion layer CCL through total reflection. For example, the optical layer OPL may have a refractive index relatively lower than a refractive index of the color conversion layer CCL. For example, the refractive index of the color conversion layer may be about 1.6 to about 2.0, and the refractive index of the optical layer OPL may be about 1.1 to about 1.3.

A second capping layer CPL2 may be disposed on the optical layer OPL. The second capping layer CPL2 may be provided (or disposed) throughout the first to third pixels PXL1, PXL2, and PXL3. The second capping layer CPL2 may cover the optical layer OPL. The second capping layer CPL2 may protect the optical layer OPL from being damaged or contaminated due to infiltration (or permeation) of an impurity such as moisture or air from the outside.

The second capping layer CPL2 may be an inorganic layer, and may include silicon nitride (SiNₓ), aluminum nitride (AlNₓ), titanium nitride (TiNₓ), silicon oxide (SiOₓ), aluminum oxide (AlOₓ), titanium oxide (TiOₓ), silicon oxycarbide (SiOₓC_{y}), silicon oxynitride (SiOₓN_{y}), and the like.

A planarization layer PLL may be disposed on the second capping layer CPL2. The planarization layer PLL may be provided (or disposed) throughout the first to third pixels PXL1, PXL2, and PXL3.

The planarization layer PLL may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the planarization layer PLL may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

The color filter layer CFL may be disposed on the planarization layer PLL. The color filter layer CFL may include color filters CF1, CF2, and CF3 according to a color of each pixel PXL. The color filters CF1, CF2, and CF3 according to colors of the respective first to third pixels PXL1, PXL2, and PXL3 may be disposed, so that a full-color image may be displayed.

The color filter layer CFL may include a first color filter CF1 disposed in the first pixel PXL1 such that light emitted from the first pixel PXL1 may be selectively transmitted therethrough, a second color filter CF2 disposed in the second pixel PXL2 such that light emitted from the second pixel PXL2 may be selectively transmitted therethrough, and a third color filter CF3 disposed in the third pixel PXL3 such that light emitted from the third pixel PXL3 may be selectively transmitted therethrough.

In an embodiment, the first color filter CF1, the second color filter CF2, and the third color filter CF3 may be respectively a red color filter, a green color filter, and a blue color filter, but embodiments are not limited thereto. Hereinafter, in case that an arbitrary color filter among the first color filter CF1, the second color filter CF2, and the third color filter CF3 is designated or in case that two or more kinds of color filters are inclusively designated, the corresponding color filter or the corresponding color filters are referred to as a “color filter” or “color filters.”

The first color filter CF1 may overlap the first color conversion layer CCL1 of the first pixel PXL1 in the third direction (e.g., Z-axis direction). The first color filter CF1 may include a color filter material for selectively transmitting light of a first color (or red). For example, in case that the first pixel PXL1 is a red pixel, the first color filter CF1 may include a red color filter material.

The second color filter CF2 may overlap the second color conversion layer CCL2 of the second pixel PXL2 in the third direction (e.g., Z-axis direction). The second color filter CF2 may include a color filter material for selectively transmitting light of a second color (or green). For example, in case that the second pixel PXL2 is a green pixel, the second color filter CF2 may include a green color filter material.

The third color filter CF3 may overlap the light scattering layer LSL of the third pixel PXL3 in the third direction (e.g., Z-axis direction). The third color filter CF3 may include a color filter material for selectively transmitting light of a third color (or blue). For example, in case that the third pixel PXL3 is a blue pixel, the third color filter CF3 may include a blue color filter material.

In some embodiments, a light blocking layer BM may be further disposed between the first to third color filters CF1, CF2, and CF3. As such, in case that the light blocking layer BM is formed between the first to third color filters CF1, CF2, and CF3, a color mixture defect viewed at the front or side of the display device may be prevented. The material of the light blocking layer BM is not limited, and the light blocking layer BM may be formed of various light blocking materials. In an example, the light blocking layer BM may be implemented by stacking the first to third color filters CF1, CF2, and CF3.

An overcoat layer OC may be disposed on the color filter layer CFL. The overcoat layer OC may be provided (or disposed) throughout the first to third pixels PXL1, PXL2, and PXL3. The overcoat layer OC may cover a lower member including the color filter layer CFL. The overcoat layer OC may prevent moisture or air from infiltrating (or permeating) into the above-described lower member. The overcoat layer OC may protect the above-described lower member from a foreign matter such as dust.

The overcoat layer OC may include an organic material such as acrylic resin, epoxy resin, phenolic resin, polyamide resin, polyimide resin, unsaturated polyester resin, poly-phenylene ether resin, poly-phenylene sulfide resin, or benzocyclobutene (BCB). However, embodiments are not limited thereto, and the overcoat layer OC may include various kinds of inorganic insulating materials, including silicon oxide (SiOₓ), silicon nitride (SiNₓ), silicon oxynitride (SiOₓN_{y}), aluminum nitride (AlNₓ), aluminum oxide (AlOₓ), zirconium oxide (ZrOₓ), hafnium oxide (HfOₓ), and titanium oxide (TiOₓ).

Continuously, a method of manufacturing the display device in accordance with the above-described embodiment will be described.

FIGS. 17 to 25 are schematic plan and cross-sectional views illustrating process steps of a method of manufacturing the display device in accordance with an embodiment. Hereinafter, components substantially identical to those shown in FIGS. 1 to 16 are designated by like reference numerals, and detailed reference numerals are omitted.

Referring to FIGS. 17 to 19, first, electrodes ALE may be formed in a pixel PXL. First to third electrodes ALE1, ALE2, and ALE3 may extend in the second direction (e.g., Y-axis direction), and be spaced apart from each other in the first direction (e.g., X-axis direction).

The electrodes ALE may be formed above signal lines SG1, SG2, and SG3. Each of the signal lines SG1, SG2, and SG3 may correspond to some of the first scan line S1, the second scan line S2, the data lines D1, D2, and D3, the power line PL, the initialization power line IPL, and/or the storage capacitor Cst, which are described with reference to FIG. 5.

The signal lines SG1, SG2, and SG3 may at least partially overlap alignment areas ALA1 and ALA2 in the third direction (e.g., Z-axis direction). A first alignment area ALA1 may mean an area between the first electrode ALE1 and the second electrode ALE2, and a second alignment area ALA2 may mean an area between the second electrode ALE2 and the third electrode ALE3.

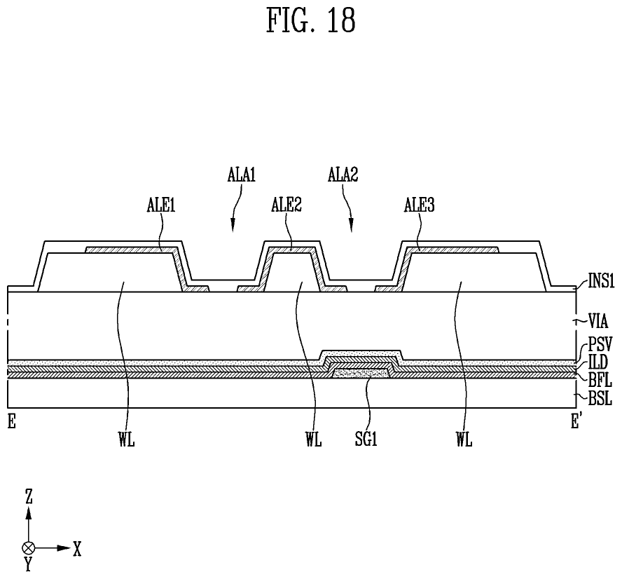

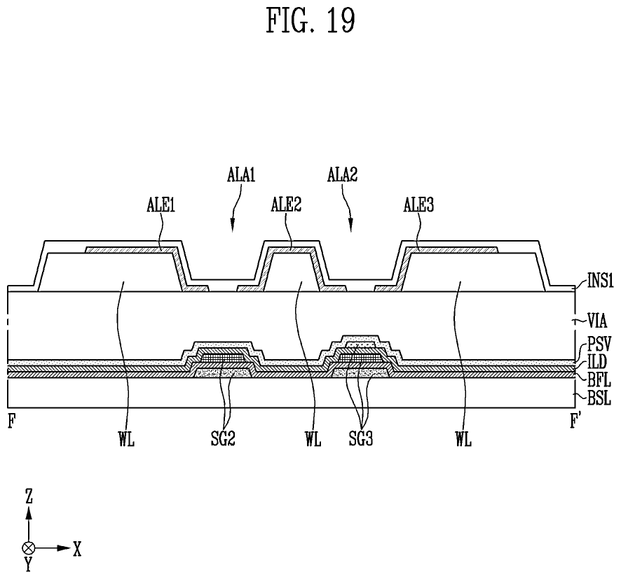

In FIGS. 18 and 19, a first signal line SG1 may overlap the second alignment area ALA2 in the third direction (e.g., Z-axis direction), a second signal line SG2 may overlap the first alignment area ALA1 in the third direction (e.g., Z-axis direction), and a third signal line SG3 may overlap the second alignment area ALA2 in the third direction (e.g., Z-axis direction). However, embodiments are not limited thereto.

The first signal line SG1 may be formed as a single layer. In an example, the first signal line SG1 may be formed of the above-described first conductive layer. However, embodiments are not limited thereto, and the first signal line SG1 may be formed of the above-described second conductive layer or the above-described third conductive layer.

The second signal line SG2 may be formed of a double layer. In an example, the second signal line SG2 may be formed of the first conductive layer and the second conductive layer. The first conductive layer and the second conductive layer of the second signal line SG2 may overlap each other in the third direction (e.g., Z-axis direction). However, embodiments are not limited thereto, and the second signal line SG2 may be formed of the first conductive layer and the third conductive layer, or be formed of the second conductive layer and the third conductive layer.

The third signal line SG3 may be formed of a triple layer. In an example, the third signal line SG3 may be formed of the first conductive layer, the second conductive layer, and the third conductive layer. The first conductive layer, the second conductive layer, and the third conductive layer of the third signal line SG3 may overlap each other in the third direction (Z-axis direction).

The signal lines SG1, SG2, and SG3 may be electrically separated from the electrodes ALE. Accordingly, the electrodes ALE and the signal lines SG1, SG2, and SG3 may be separated from each other, thereby supplying different alignment voltages to the electrodes ALE and the signal lines SG1, SG2, and SG3.

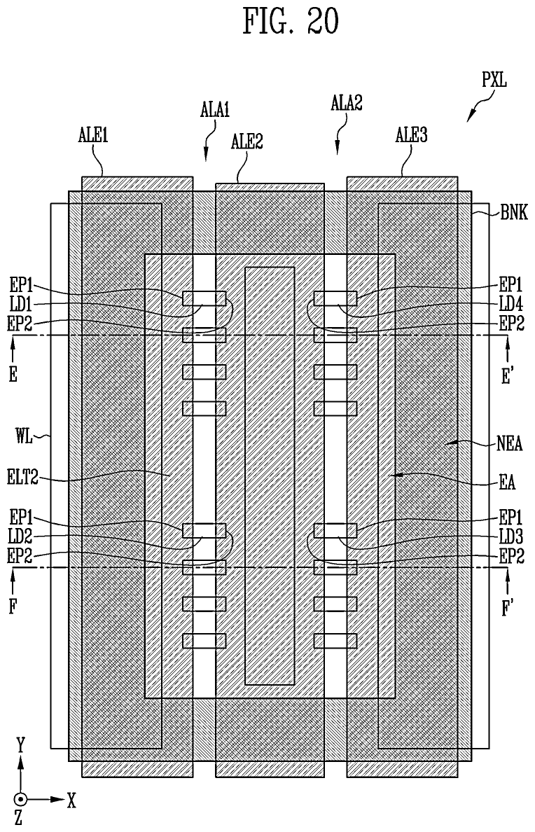

Referring to FIGS. 20 to 22, light emitting elements LD may be aligned between the electrodes ALE (or in the alignment areas ALA1 and ALA2).

The light emitting elements LD may be prepared in a form in which the light emitting elements LD are dispersed in a light emitting element ink, to be supplied by an inkjet printing process, or the like. In an example, the light emitting elements LD may be provided with being dispersed in a volatile solvent.

Subsequently, an alignment voltage may be applied to the electrodes ALE and the signal lines SG1, SG2, and SG3, thereby aligning the light emitting elements LD. In a step of aligning the light emitting elements LD, a first alignment voltage may be applied to the electrodes ALE, a second alignment voltage may be applied to the first signal line SG1, a third alignment voltage may be applied to the second signal line SG2, and a fourth alignment voltage may be applied to the third signal line SG3.

In an embodiment, the first alignment voltage may be higher than the second alignment voltage. The second alignment voltage may be higher than the third alignment voltage. The third alignment voltage may be higher than the fourth alignment voltage. In an example, the second alignment voltage may be is equal to or lower than about 65% of the first alignment voltage, the third alignment voltage may be equal to or lower than about 60% of the first alignment voltage, and the fourth alignment voltage may be equal to or lower than about 55% of the first alignment voltage.

In the step of aligning the light emitting elements LD, the first alignment voltage, the second alignment voltage, the third alignment voltage, and/or the fourth alignment voltage may be simultaneously applied. As such, in case that the second to fourth alignment voltages are respectively applied to the first to third signal lines SG1, SG2, and SG3 at the same time in case that the first alignment voltage is applied to the electrodes ALE, electric field asymmetry formed in the alignment areas ALA1 and ALA2 may be reduced or prevented. In general, in case that the first alignment voltage is applied to only the electrodes ALE, a difference in electric field strength between the alignment areas ALA1 and ALA2 may be averagely 6.9%. In case that the second alignment voltage is applied to the first signal line SG1 at the same time in case that the first alignment voltage is applied to the electrodes ALE, the difference in electric field strength between the alignment areas ALA1 and ALA2 may be improved as averagely 0.4%. In case that the third alignment voltage is applied to the second signal line SG2 at the same time in case that the first alignment voltage is applied to the electrodes ALE, the difference in electric field strength between the alignment areas ALA1 and ALA2 may be improved as averagely 0.1%. In case that the fourth alignment voltage is applied to the third signal line SG3 at the same time in case that the first alignment voltage is applied to the electrodes ALE, the difference in electric field strength between the alignment areas ALA1 and ALA2 may be improved as averagely 1.4%. For example, as the second to fourth alignment voltages are respectively applied to the first to third signal lines SG1, SG2, and SG3 at the same time in case that the first alignment voltage is applied to the electrodes ALE, the electric field asymmetry of the alignment areas ALA1 and ALA2 may be reduced or prevented, thereby improving the alignment degree of the light emitting elements LD.

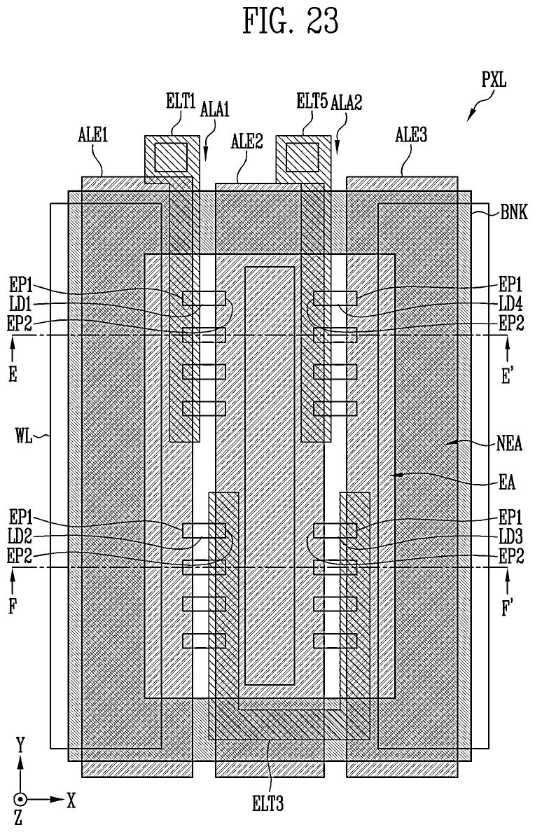

Referring to FIGS. 23 to 25, subsequently, connection electrodes ELT may be formed on the light emitting elements LD. In an embodiment, the connection electrodes ELT may be electrically connected to first and second end portions EP1 and EP2 of the light emitting elements LD. Some of the connection electrodes ELT may be electrically connected to some of the above-described first to third signal lines SG1, SG2, and SG3.

As described with reference to FIGS. 9 and 11, the connection electrodes ELT may be formed of conductive layers. For example, a second insulating layer INS2 may be formed on the light emitting elements LD, and a first connection electrode ELT1, a third connection electrode ELT3, and a fifth connection electrode ELT5 may be formed on the second insulating layer INS2. A third insulating layer INS3 may be formed over the first connection electrode ELT1, the third connection electrode ELT3, and the fifth connection electrode ELT5. A second connection electrode ELT2 and a fourth connection electrode ELT4 may be formed on the third insulating layer INS3. However, embodiments are not limited thereto, and the first to fifth connection electrodes ELT1, ELT2, ELT3, ELT4, and ELT4 may be formed of the same conductive layer as described with reference to FIGS. 13 and 14.

Hereinafter, another embodiment will be described. In the following embodiment, components identical to those which have already been described are designated by like reference numerals, and overlapping descriptions will be omitted or simplified.

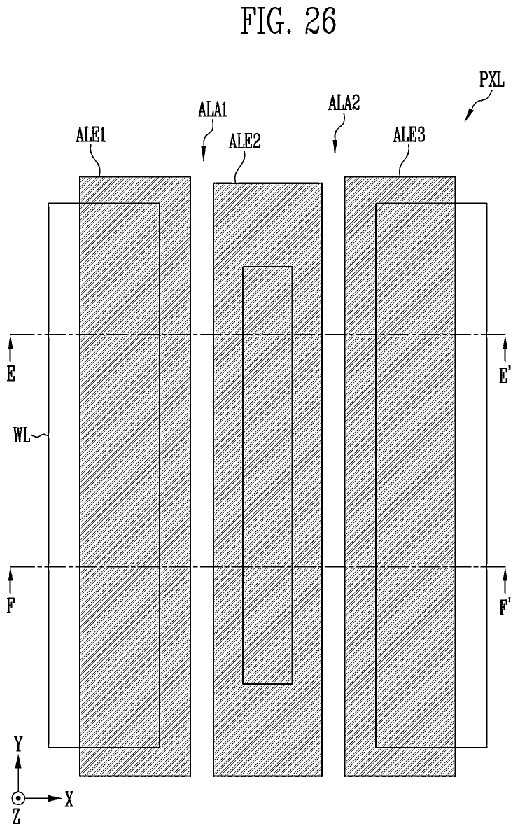

FIGS. 26 to 34 are schematic plan views and schematic cross-sectional views illustrating process steps of a method of manufacturing the display device in accordance with an embodiment.

Referring to FIGS. 26 to 34, an electrode layer MTL may be further formed below electrodes ALE. The electrode layer MTL may be formed of the above-described fourth conductive layer.

The electrode layer MTL may at least partially overlap alignment areas ALA1 and ALA2 in the third direction (e.g., Z-axis direction). The electrode layer MTL may at least partially overlap the electrodes ALE in the third direction (e.g., Z-axis direction). The electrode layer MTL may at least partially overlap first to third signal lines SG1, SG2, and SG3 in the third direction (e.g., Z-axis direction).

The electrode layer MTL may be electrically separated from the electrodes ALE. The electrode layer MTL may be electrically separated from the first to third signal lines SG1, SG2, and SG3. Accordingly, as the electrodes ALE, the signal lines SG1, SG2, and SG3, and the electrode layer MTL are separated from each other, difference alignment voltages may be applied to the electrodes ALE, the signal lines SG1, SG2, and SG3, and the electrode layer MTL.

Referring to FIGS. 29 to 31, light emitting elements LD may be aligned between the electrodes ALE (or in the alignment areas ALA1 and ALA2).

An alignment voltage may be applied to the electrodes ALE, the signal lines SG1, SG2, and SG3, and the electrode layer MTL, thereby aligning the light emitting elements LD. In a step of aligning the light emitting elements LD, a first alignment voltage may be applied to the electrodes ALE, a second alignment voltage may be applied to the first signal line SG1, a third alignment voltage may be applied to the second signal line SG2, a fourth alignment voltage may be applied to the third signal line SG3, and a fifth alignment voltage may be applied to the electrode layer MTL.

In the step of aligning the light emitting elements LD, the first alignment voltage, the second alignment voltage, the third alignment voltage, the fourth alignment voltage, and/or the fifth alignment voltage may be simultaneously applied. As such, in case that the second to fifth alignment voltages are respectively applied to the signal lines SG1, SG2, and SG3 and the electrode layer MTL at the same time in case that the first alignment voltage is applied to the electrodes ALE, the electric field asymmetry formed in the alignment areas ALA1 and ALA2 may be reduced or prevented, thereby improving the alignment degree of the light emitting elements LD, which has been described above.

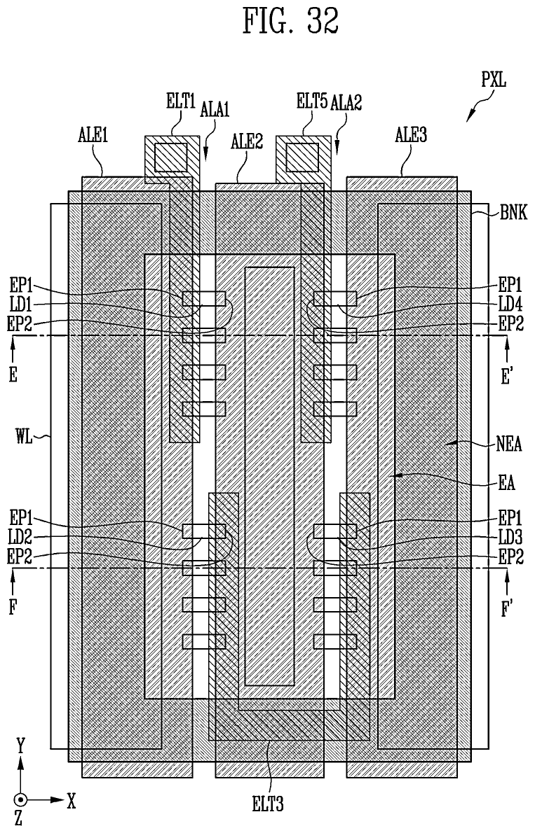

Referring to FIGS. 32 to 34, subsequently, connection electrodes ELT may be formed on the light emitting elements LD. Some of the connection electrodes ELT may be electrically connected to some of the above-described first to third signal lines SG1, SG2, and SG3.

In accordance with the disclosure, an alignment voltage is simultaneously applied to electrodes and signal lines, so that electric field asymmetry of an alignment area may be reduced or prevented, thereby improving the alignment degree of light emitting elements.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A method of manufacturing a display device, the method comprising:
aligning light emitting elements in an alignment area between electrodes spaced apart from each other, wherein
the aligning of the light emitting elements includes:
applying a first alignment voltage to the electrodes,
applying a second alignment voltage to a first signal line overlapping the alignment area, and
applying a third alignment voltage to a second signal line overlapping the alignment area,
the first signal line is formed of a first conductive layer, and
the second signal line is formed of the first conductive layer and a second conductive layer.

2. The method of claim 1, wherein the first alignment voltage, the second alignment voltage, and the third alignment voltage are simultaneously applied.

3. The method of claim 1, wherein the first alignment voltage is higher than the second alignment voltage.

4. The method of claim 1, wherein the second alignment voltage is higher than the third alignment voltage.

5. The method of claim 1, wherein the electrodes are electrically separated from the first signal line and the second signal line.

6. The method of claim 1, wherein the aligning of the light emitting elements includes applying a fourth alignment voltage to a third signal line overlapping the alignment area.

7. The method of claim 6, wherein the third signal line is formed of the first conductive layer, the second conductive layer, and a third conductive layer.

8. The method of claim 6, wherein the first alignment voltage, the second alignment voltage, the third alignment voltage, and the fourth alignment voltage are simultaneously applied.

9. The method of claim 6, wherein the third alignment voltage is higher than the fourth alignment voltage.

10. The method of claim 6, wherein the electrodes are electrically separated from the third signal line.

11. The method of claim 1, wherein the aligning of the light emitting elements includes applying a fifth alignment voltage to an electrode layer overlapping the alignment area.

12. The method of claim 11, wherein the electrode layer is formed of a fourth conductive layer.

13. The method of claim 11, wherein the electrode layer overlaps the first signal line or the second signal line.

14. The method of claim 11, wherein the first alignment voltage, the second alignment voltage, the third alignment voltage, and the fifth alignment voltage are simultaneously applied.

15. The method of claim 11, wherein the first alignment voltage is higher than the fifth alignment voltage.

16. The method of claim 11, wherein the electrodes are electrically separated from the electrode layer.

17. The method of claim 11, wherein the electrode layer is electrically separated from the first signal line and the second signal line.

18. The method of claim 11, wherein the electrode layer overlaps the electrodes.

19. The method of claim 1, further comprising:
forming connection electrodes on the light emitting elements.

20. The method of claim 19, wherein the connection electrodes are electrically connected to the first signal line or the second signal line.
